(19) United States
(12) Patent Application Publication
(10) Pub. No.: US 2025/0203795 A1
(43) Pub. Date: Jun. 19, 2025

(54) FOLDABLE APPARATUS AND METHOD OF MAKING THE SAME

(71) Applicant: CORNING INCORPORATED, CORNING, NY (US)

(72) Inventors: YOUSEF KAYED QAROUSH, PAINTED POST, NY (US); TINGGE XU, SAN JOSE, CA (US)

(21) Appl. No.: 18/847,388

(22) PCT Filed: Mar. 13, 2023
(86) PCT No.: PCT/US2023/015091

§ 371 Date: Sep. 16, 2024

Related U.S. Application Data
(60) Provisional application No. 63/319,489, filed on Mar. 14, 2022.

(51) Int. Cl. H05K 5/03; B32B 7/12; B32B 17/10

(52) U.S. Cl. CPC H05K 5/03; B32B 7/12; B32B 17/10; B32B 2307/546; B32B 2307/7376; B32B 2457/20

(57) ABSTRACT

Foldable apparatus comprise a foldable substrate comprising a first portion, a second portion, and a central portion positioned therebetween. The first portion and the second portion comprise a substrate thickness. The central portion comprises a central thickness that is less than the substrate thickness. A first central surface area of the central portion is recessed from the first major surface by a first difference and defines a first recess. The foldable apparatus comprises a first adhesive layer disposed in the first recess. The first adhesive layer comprises a first adhesive thickness of about 5 micrometers or more. The first adhesive layer comprises an elastic modulus of about 0.4 MegaPascals of less. The foldable apparatus comprises a first polymer-based portion disposed on the first adhesive layer such that the first adhesive layer is positioned between the first central surface area and the first polymer-based portion.

### CROSS-REFERENCE TO RELATED APPLICATION

This application claims the benefit of priority under 35 U.S.C. § 119 of U.S. Provisional Application Ser. No. 63/319,489 filed on Mar. 14, 2022, the content of which is relied upon and incorporated herein by reference in its entirety.

### FIELD

The present disclosure relates generally to foldable apparatus and methods of making the same and, more particularly, to foldable apparatus comprising a foldable substrate, a polymer-based portion, and an adhesive layer.

### BACKGROUND

Foldable substrates are commonly used, for example, in display applications, for example, liquid crystal displays (LCDs), electrophoretic displays (EPD), organic light-emitting diode displays (OLEDs), plasma display panels (PDPs), or the like.

There is a desire to develop foldable displays as well as foldable protective covers to mount on foldable displays. Foldable displays and foldable covers should have good impact and puncture resistance. At the same time, foldable displays and foldable covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 μm) with good impact and/or puncture resistance tend to have relatively large minimum bend radii (e.g., about 30 mm or more). Moreover, foldable apparatus comprising thicker glass-based sheets can suffer from fatigue-related failure and/or have issues with mechanical reliability.

Consequently, there is a need to develop foldable apparatus that have low minimum bend radii and good impact and puncture resistance. Further, there is a need to develop foldable apparatus with reduced fatigue-based failure and/or good mechanical reliability.

### SUMMARY

There are set forth herein foldable apparatus and methods of making foldable apparatus that comprise foldable substrates. The foldable substrate can provide a small parallel plate distance while simultaneously providing good impact and puncture resistance. The foldable apparatus can comprise glass-based and/or ceramic-based materials comprising one or more compressive stress regions, which can further provide increased impact resistance and/or puncture resistance while simultaneously facilitating good bending performance.

Providing an adhesive layer between a polymer-based portion and a central surface area of the foldable substrate can provide a neutral plane within the first adhesive portion. Providing a low elastic modulus (e.g., about 0.4 MPa or less), a thickness of about 5 μm or more, and/or a low flexural rigidity (e.g., about 10⁻⁷ Pa m³ or less) can enable a neutral plane within the adhesive layer and/or reduce bend-induced stresses in adjacent first portions, which can reduce the incidence of bend-induced mechanical instabilities.

Providing an adhesive layer and/or a polymer-based portion with a glass transition temperature outside of an operating range (e.g., from about 0° C. to about 40° C., from about −20° C. to about 60° C.) of a foldable apparatus can enable the foldable apparatus to have consistent properties across the operating range. Providing an adhesive layer comprising a much lower (e.g., from about 500 times to about 500,000 times, from about 10,000 times to about 100,000 times) elastic modulus and/or flexural rigidity than a polymer-based portion can reduce bend-induced stresses on the polymer-based portion or the foldable substrate. Reducing bend-induced stresses can reduce (e.g., decreases, eliminate) bend-induced mechanical instabilities of the foldable apparatus. Also, reducing bend-induced stresses can reduce fatigue of the foldable apparatus while increasing the reliability and/or durability of the foldable apparatus. Without wishing to be bound by theory, it is believed that the neutral planes introduced by providing the adhesive layer between the polymer-based portion and the foldable substrate enable decoupling of the stiffer layers (i.e., foldable substrate, polymer-based portions). Providing more than one neutral plane (e.g., second neutral plane) can reduce (e.g., mitigate, avoid) instabilities of foldable apparatus during folding the foldable apparatus. Providing a foldable substrate where the number of neutral planes is equal to one less than the sum of the number of first regions (e.g., polymer-based portions and foldable substrate) and the number of second regions (e.g., adhesive layers) can enable decoupling of the first regions, which can result in a reduced bend force, reduced incidence of mechanical instabilities, reduced bend-induced stresses and/or strains, and/or reduced failure of the foldable apparatus. Providing a foldable apparatus with an apparatus bend force near (e.g., within a factor of 2, from about 0.5 times to about 1 times) a total bend force from bending each first portion individually can enable low user-applied forces to fold the foldable apparatus. Also, this can reflect a decreased coupling of bend-induced stresses between adjacent pairs of first portions.

Providing a low (e.g., 4% or less) strain of the first polymer-based portion when the foldable apparatus achieves a parallel plate distance of 3 mm can reduce requirements for the first polymer-based portion, which can reduce failure of the foldable apparatus, and/or enable the use of a wider range of materials for the polymer-based portion since the strain requirements have been eased. Providing a low (e.g., 900 MPa or less) bending stress on the central portion of the foldable apparatus when the foldable apparatus achieves a parallel plate distance of 3 mm can decrease a bend force and/or reduce failure of the foldable apparatus. Providing one or more indices of refraction that substantially matches an index of refraction of the foldable substrate

Some Example aspects of the disclosure are described below with the understanding that any of the features of the various aspects may be used alone or in combination with one another.

Aspect 1. A foldable apparatus comprising:
a foldable substrate comprising:
a substrate thickness defined between a first major surface and a second major surface opposite the first major surface, the substrate thickness is in a range from about 100 micrometers to about 2 millimeters;
a first portion comprising the substrate thickness;
a second portion comprising the substrate thickness; and
a central portion positioned between the first portion and the second portion, the central portion comprising a central thickness defined between a first central surface area and a second central surface area opposite the first central surface area, and the central thickness is less than the substrate thickness, the first central surface area is recessed from the first major surface by a first distance and defines a first recess;
a first adhesive layer disposed in the first recess, the first adhesive layer comprising a first adhesive thickness of about 5 micrometers or more, the first adhesive layer comprising an elastic modulus of about 0.4 MegaPascals or less; and
a first polymer-based portion disposed on the first adhesive layer such that the first adhesive layer is positioned between the first central surface area and the first polymer-based portion.

Aspect 2. The foldable apparatus of aspect 1, wherein the first adhesive thickness is defined between a first contact surface of the first adhesive layer facing the first polymer-based portion and a second contact surface of the first adhesive layer facing the first central surface area, the first contact surface and the second contact surface face opposite directions, the first polymer-based portion comprising a first polymer thickness defined between a third contact surface and a fourth contact surface facing the first adhesive layer, the third contact surface of the first polymer-based portion and the fourth contact surface of the first polymer-based portion facing opposite directions, and the first contact surface contacts the fourth contact surface.

Aspect 3. The foldable apparatus of aspect 2, wherein an absolute value of a strain of the first polymer-based portion at the third contact surface is about 4% or less when the foldable apparatus achieves a parallel plate distance of 3 millimeters.

Aspect 4. The foldable apparatus of aspect 2, wherein an absolute value of a bending stress of the central portion at the first central surface area is about 900 MegaPascals or less when the foldable apparatus achieves a parallel plate distance of 3 millimeters.

Aspect 5. The foldable apparatus of aspect 2, wherein a bend force to achieve a parallel plate distance of 3 millimeters is about 0.01 Newtons per millimeter width of the foldable apparatus (N/mm) or less.

Aspect 6. The foldable apparatus of aspect 2, wherein the foldable apparatus is configured to achieve a parallel plate distance of 3 millimeters.

Aspect 7. The foldable apparatus of aspect 2, wherein the foldable apparatus is configured to achieve a parallel plate distance in a range from about 1 millimeter to about 10 millimeters.

Aspect 8. The foldable apparatus of any one of aspects 2-7, wherein the fourth contact surface of the first polymer-based portion contacts a first surface area of the first portion, the first surface area opposite a second surface area of the first portion with the substrate thickness therebetween, the fourth contact surface of the first polymer-based portion contacts a third surface area of the second portion, the third surface area opposite a fourth surface area of the second portion with the substrate thickness therebetween.

Aspect 9. The foldable apparatus of any one of aspects 1-8, wherein the first adhesive thickness is less than the first distance.

Aspect 10. The foldable apparatus of aspect 9, wherein the first adhesive thickness is less than the first distance by about 10 micrometers or more.

Aspect 11. The foldable apparatus of any one of aspects 1-8, wherein the first adhesive thickness is substantially equal to the first distance.

Aspect 12. The foldable apparatus of any one of aspects 1-7, wherein the first adhesive layer is positioned between the first polymer-based portion and the first portion, and the first adhesive layer is positioned between the first polymer-based portion and the second portion.

Aspect 13. The foldable apparatus of any one of aspects 1-7 or 12 inclusive, wherein the first adhesive thickness is greater than the first distance by about 5 micrometers or more.

Aspect 14. The foldable apparatus of any one of aspects 1-13, wherein a ratio of an elastic modulus of the first polymer-based portion to the elastic modulus of the first adhesive layer is about 500 times or more.

Aspect 15. The foldable apparatus of any one of aspects 1-13, wherein the first polymer-based portion comprises an elastic modulus of about 1 GigaPascal or more.

Aspect 16. The foldable apparatus of claim 15, wherein the elastic modulus of the first polymer-based portion is in a range from about 1 GigaPascal to about 10 GigaPascals.

Aspect 17. The foldable apparatus of any one of aspects 1-16, wherein the first polymer-based portion comprises a strain at yield in a range from about 3% to about 10%.

Aspect 18. The foldable apparatus of any one of aspects 1-17, wherein a magnitude of a difference between an index of refraction of the foldable substrate and an index of refraction of the first polymer-based portion is about 0.1 or less.

Aspect 19. The foldable apparatus of any one of aspects 1-17, wherein a magnitude of a difference between an index of refraction of the foldable substrate and an index of refraction of the first adhesive layer is about 0.1 or less.

Aspect 20. The foldable apparatus of any one of aspects 1-19, wherein the second major surface is continuous with the second central surface area.

Aspect 21. The foldable apparatus of aspect 20, wherein the first distance is about 20% to about 45% of the substrate thickness.

Aspect 22. The foldable apparatus of any one of aspects 1-19, wherein the second central surface area is recessed from the second major surface by a second distance and defines a second recess.

Aspect 23. The foldable apparatus of aspect 22, wherein the second distance is from about 5% to about 20% of the substrate thickness.

Aspect 24. The foldable apparatus of any one of aspects 22-23, wherein the first distance is substantially equal to the second distance.

Aspect 25. The foldable apparatus of any one of aspects 22-24, wherein the foldable apparatus further comprising:
a second adhesive layer positioned in the second recess, the second adhesive layer comprising a second adhesive thickness; and
a second polymer-based portion disposed on the second adhesive layer such that the second adhesive layer is positioned between the second polymer-based portion and the second central surface area.

Aspect 26. The foldable apparatus of aspect 25, wherein the second adhesive thickness is less than the second distance by about 10 micrometers or more.

Aspect 27. The foldable apparatus of aspect 25, wherein the second adhesive thickness is substantially equal to the second distance.

Aspect 28. The foldable apparatus of aspect 25, wherein the second adhesive layer is positioned between the second polymer-based portion and the first portion, and the second adhesive layer is positioned between the second polymer-based portion and the second portion.

Aspect 29. The foldable apparatus of aspect 25 or aspect 28, wherein the second adhesive thickness is greater than the second thickness by about 5 micrometers or more.

Aspect 30. The foldable apparatus of any one of aspects 25-29, wherein the second polymer-based portion comprises a pencil hardness of about 5H or more, and the second polymer-based portion comprises an elastic modulus of about 1 GigaPascal or more.

Aspect 31. The foldable apparatus of any one of aspects 20-24, wherein the foldable apparatus further comprises a coating disposed on the second major surface, the coating comprises a pencil hardness of about 5H or more, and the coating comprises an elastic modulus of about 1 GigaPascal or more.

Aspect 32. The foldable apparatus of any one of aspects 1-31, wherein the foldable substrate comprises a first neutral plane extending through the first portion, the second portion, and the central portion, the first adhesive layer comprises a second neutral plane, and the polymer-based portion comprises an another first neutral plane.

Aspect 33. The foldable apparatus of any one of aspects 1-32, wherein an apparatus bend force is in a range from about 0.5 times to about 1 times a total bend force comprising a force to bend each component of the foldable apparatus individually.

Aspect 34. The foldable apparatus of any one of aspects 1-33, wherein a width of central portion defined between the first portion and the second portion is in a range from about 10 millimeters to about 30 millimeters.

Aspect 35. The foldable apparatus of any one of aspects 1-34, wherein the foldable substrate comprises a glass-based substrate or a ceramic-based substrate.

Aspect 36. The foldable apparatus of any one of aspects 1-35, wherein the substrate thickness is in a range from about 125 micrometers to about 200 micrometers.

Aspect 37. The foldable apparatus of any one of aspects 1-36, wherein the central thickness is in a range from about 10 micrometers to about 80 micrometers.

Aspect 38. The foldable apparatus of aspect 37, wherein the central thickness is in a range from about 25 micrometers to about 60 micrometers.

Aspect 39. The foldable apparatus of any one of aspects 1-38, wherein:
the first portion comprises a first compressive stress region extending to a first depth of compression from the first major surface, a second compressive stress region extending to a second depth of compression from the second major surface, a first depth of layer of one or more alkali metal ions associated with the first depth of compression, and a second depth of layer of one or more alkali metal ions associated with the second depth of compression;
the second portion comprises a third compressive stress region extending to a third depth of compression from the first major surface, a fourth compressive stress region extending to a fourth depth of compression from the second major surface, a third depth of layer of one or more alkali metal ions associated with the third depth of compression, and a fourth depth of layer of one or more alkali metal ions associated with the fourth depth of compression; and
the central portion comprises a fifth compressive stress region extending to a fifth depth of compression from the first central surface area, a sixth compressive stress region extending to a sixth depth of compression from the second central surface area, a fifth depth of layer of one or more alkali metal ions associated with the fifth depth of compression, a sixth depth of layer of the one or more alkali metal ions associated with the sixth depth of compression.

Aspect 40. The foldable substrate of aspect 39, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, the fourth compressive stress region comprises a fourth maximum compressive stress, the fifth compressive stress region comprises a fifth maximum compressive stress of about 400 MegaPascals or more, and the sixth compressive stress region comprises a sixth maximum compressive stress.

Aspect 41. The foldable substrate of aspect 40, wherein the second maximum compressive stress is about 400 MegaPascals or more, the fourth maximum compressive stress is about 400 MegaPascals or more, and the sixth maximum compressive stress is about 400 MegaPascals or more.

Aspect 42. The foldable apparatus of any one of aspects 1-40, further comprising a display device attached to the first polymer-based portion.

Aspect 43. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed on the display,
wherein at least one of a portion of the housing or the cover substrate comprises the foldable apparatus of any one of aspects 1-42.

Aspect 44. A method of forming a foldable apparatus comprising:
disposing a first adhesive layer in a first recess defined between a first major surface of a foldable substrate and a first central surface area of the foldable substrate, the first adhesive layer comprising a first adhesive thickness defined between a first contact surface of the first adhesive layer and a second contact surface of the first adhesive layer, the first adhesive thickness is about 5 micrometers or more; and
disposing a first polymer-based portion on the first adhesive layer, the first portion, and the second portion, the first polymer-based portion comprising a third contact surface and a fourth contact surface opposite the third contact surface, the fourth contact surface facing the first adhesive layer,
wherein the foldable substrate comprises a central portion attaching a first portion to a second portion, the foldable substrate comprises a substrate thickness defined between the first major surface and a second major surface opposite the first major surface, the first portion comprises the substrate thickness, the second portion comprises the substrate thickness, the first central surface area recessed from the from the first major surface by a first distance.

Aspect 45. The method of aspect 44, wherein the first polymer-based portion contacts the first contact surface of the first adhesive layer.

Aspect 46. The method of any one of aspects 44-45, wherein the second contact surface of the first adhesive layer contacts the second central surface area.

Aspect 47. The method of any one of aspects 44-46, wherein the first distance is substantially equal to the first adhesive thickness.

Aspect 48. The method of any one of aspects 44-46, wherein the first distance is greater than the first adhesive thickness by about 10 micrometers or more.

Aspect 49. The method of any one of aspects 44-46, wherein the first adhesive thickness is greater than the first distance by about 10 micrometers or more.

Aspect 50. The method of any one of aspects 44-49, wherein the disposing the first adhesive layer comprises dispensing a first liquid into the first recess and curing the first liquid to form the first adhesive layer.

Aspect 51. The method of any one of aspects 44-49, wherein the disposing the first adhesive layer comprises disposing one or more films in the first recess.

Aspect 52. The method of any one of aspects 44-48, wherein the fourth contact surface contacts the first major surface of the foldable substrate.

Aspect 53. The method of any one of aspects 44-52, wherein an elastic modulus of the first adhesive layer is about 0.4 MegaPascals or less.

Aspect 54. The method of any one of aspects 44-53, wherein an elastic modulus of the first polymer-based portion is about 1 GigaPascal or more.

Aspect 55. The method of aspect 54, wherein the elastic modulus of the first polymer-based portion is in a range from about 1 GigaPascal to about 10 GigaPascals.

Aspect 56. The method of any one of aspects 44-51, wherein a ratio of an elastic modulus of the first polymer-based portion to an elastic modulus of the first adhesive layer is about 500 or more.

Aspect 57. The method of any one of aspects 44-56, wherein the first polymer-based portion comprises a strain at yield in a range from about 3% to about 10%.

Aspect 58. The method of any one of aspects 45-57, wherein a magnitude of a difference between an index of refraction of the foldable substrate and an index of refraction of the first polymer-based portion is about 0.1 or less.

Aspect 59. The method of any one of aspects 44-57, wherein a magnitude of a difference between an index of refraction of the foldable substrate and an index of refraction of the first adhesive layer is about 0.1 or less.

Aspect 60. The method of any one of aspects 44-59, wherein:
the first portion comprises a first compressive stress region extending to a first depth of compression from the first major surface, a second compressive stress region extending to a second depth of compression from the second major surface, a first depth of layer of one or more alkali metal ions associated with the first depth of compression, and a second depth of layer of one or more alkali metal ions associated with the second depth of compression;
the second portion comprises a third compressive stress region extending to a third depth of compression from the first major surface, a fourth compressive stress region extending to a fourth depth of compression from the second major surface, a third depth of layer of one or more alkali metal ions associated with the third depth of compression, and a fourth depth of layer of one or more alkali metal ions associated with the fourth depth of compression; and
the central portion comprises a fifth compressive stress region extending to a fifth depth of compression from the first central surface area, a sixth compressive stress region extending to a sixth depth of compression from the second central surface area, a fifth depth of layer of one or more alkali metal ions associated with the fifth depth of compression, a sixth depth of layer of the one or more alkali metal ions associated with the sixth depth of compression.

Aspect 61. The method of aspect 60, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, the fourth compressive stress region comprises a fourth maximum compressive stress, the fifth compressive stress region comprises a fifth maximum compressive stress of about 400 MegaPascals or more, and the sixth compressive stress region comprises a sixth maximum compressive stress.

Aspect 62. The method of aspect 61, wherein the second maximum compressive stress is about 400 MegaPascals or more, the fourth maximum compressive stress is about 400 MegaPascals or more, and the sixth maximum compressive stress is about 400 MegaPascals or more.

Aspect 63. The method of any one of aspects 44-62, wherein the second major surface is continuous with a second central surface area opposite the first central surface area.

Aspect 64. The method of aspect 63, wherein the first distance is about 20% to about 45% of the substrate thickness.

Aspect 65. The method of any one of aspects 44-62, wherein a second central surface area of the foldable substrate is recessed from the second major surface by a second distance and defines a second recess, the second central surface area is opposite the first central surface area.

Aspect 66. The method of aspect 65, wherein the second distance is from about 5% to about 20% of the substrate thickness.

Aspect 67. The method of any one of aspects 65-66, wherein the first distance is substantially equal to the second distance.

Aspect 68. The method of any one of aspects 65-67, further comprising: disposing a second adhesive layer in the second recess, the second adhesive layer comprising a second adhesive thickness; and disposing a second polymer-based portion on the second adhesive layer.

Aspect 69. The method of aspect 68, wherein the second adhesive thickness is less than the second distance by about 10 micrometers or more.

Aspect 70. The method of aspect 68, wherein the second adhesive thickness is substantially equal to the second distance.

Aspect 71. The method of aspect 68, wherein the second adhesive layer is positioned between the second polymer-based portion and the first portion, and the second adhesive layer is positioned between the second polymer-based portion and the second portion.

Aspect 72. The method of aspect 68 or aspect 71, wherein the second adhesive thickness is greater than the second thickness by about 5 micrometers or more.

Aspect 73. The method of any one of aspects 68-72, wherein the second polymer-based portion comprises a pencil hardness of about 5H or more, and the second polymer-based portion comprises an elastic modulus of about 1 GigaPascal or more.

Aspect 74. The method of any one of claims 63-66, further comprising disposing a coating on the second major surface, the coating comprises a pencil hardness of about 5H or more, and the coating comprises an elastic modulus of about 1 GigaPascal or more.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration in accordance with aspects of the disclosure, wherein a schematic view of the folded configuration may appear as shown in FIG. 7;

FIGS. 2-6 are schematic cross-sectional views of the foldable apparatus along line 2-2 of FIG. 1 in accordance with aspects of the disclosure;

FIG. 7 is a schematic perspective view of another example foldable apparatus in a folded configuration in accordance with aspects of the disclosure, wherein a schematic view of the flat configuration may appear as shown in FIG. 1;

FIGS. 8-9 are a cross-sectional views of the example foldable apparatus in the folded configuration along line 8-8 of FIG. 7 in accordance with aspects of the disclosure;

FIG. 10 is a schematic plan view of an example consumer electronic device according to some aspects;

FIG. 11 is a schematic perspective view of the example consumer electronic device of FIG. 10;

FIG. 12 schematically shows a view of a foldable apparatus with a mechanical instability;

FIG. 13 schematically shows a view of a foldable apparatus with another mechanical instability;

FIGS. 14-15 are plots of strain as a function of depth through the thickness of a foldable apparatus;

FIG. 16 is a plot of stress at a first central surface area of a foldable substrate of a foldable apparatus as a function of applied bend force;

FIG. 17 is a plot of stress at a second central surface area of a foldable substrate of a foldable apparatus;

FIG. 18 is a flow chart illustrating example methods making a foldable apparatus in accordance with aspects of the disclosure; and

FIGS. 19-26 schematically illustrate steps in methods of making a foldable apparatus in accordance with aspects of the disclosure.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts. However, claims may encompass many different aspects of various aspects and should not be construed as limited to the aspects set forth herein.

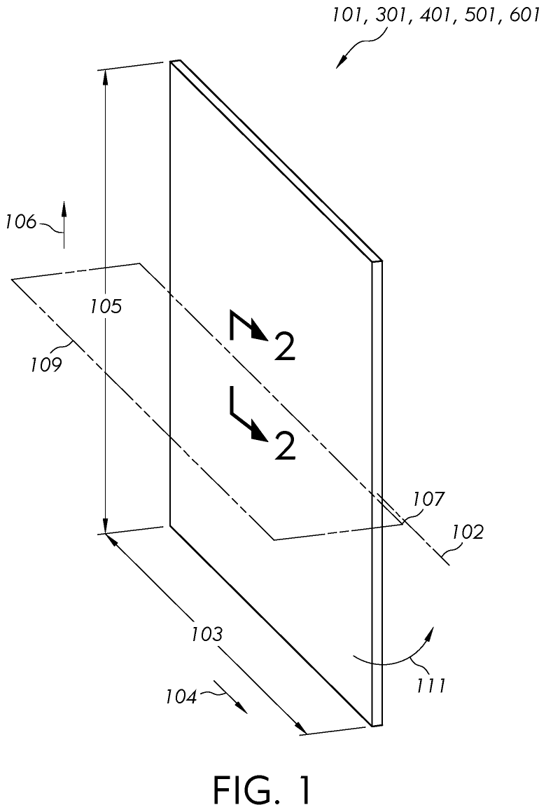

FIGS. 1-6 illustrate views of foldable apparatus 101, 301, 401, 501, and 601 in accordance with aspects of the disclosure. Unless otherwise noted, a discussion of features of aspects of one foldable apparatus can apply equally to corresponding features of any of the aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

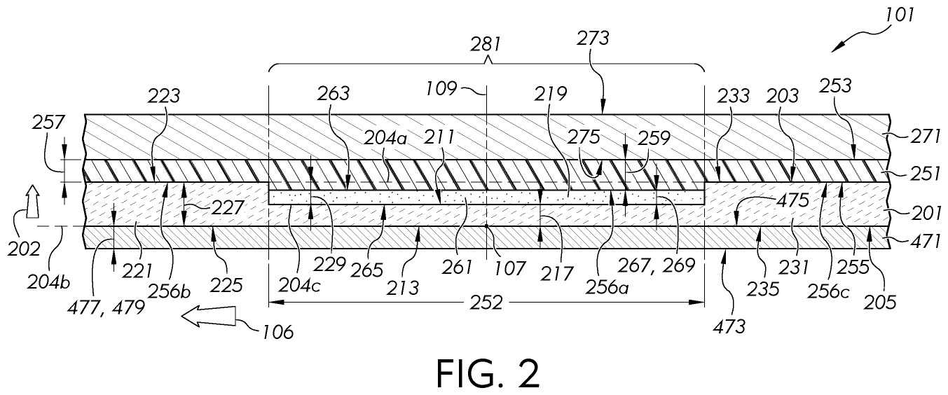

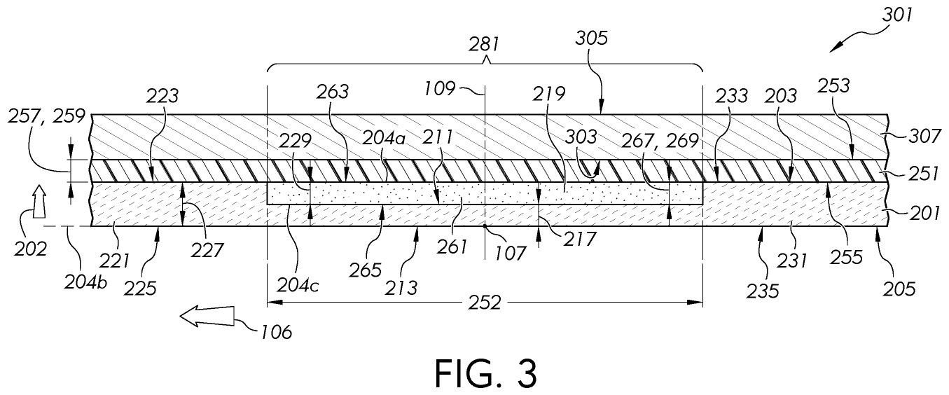

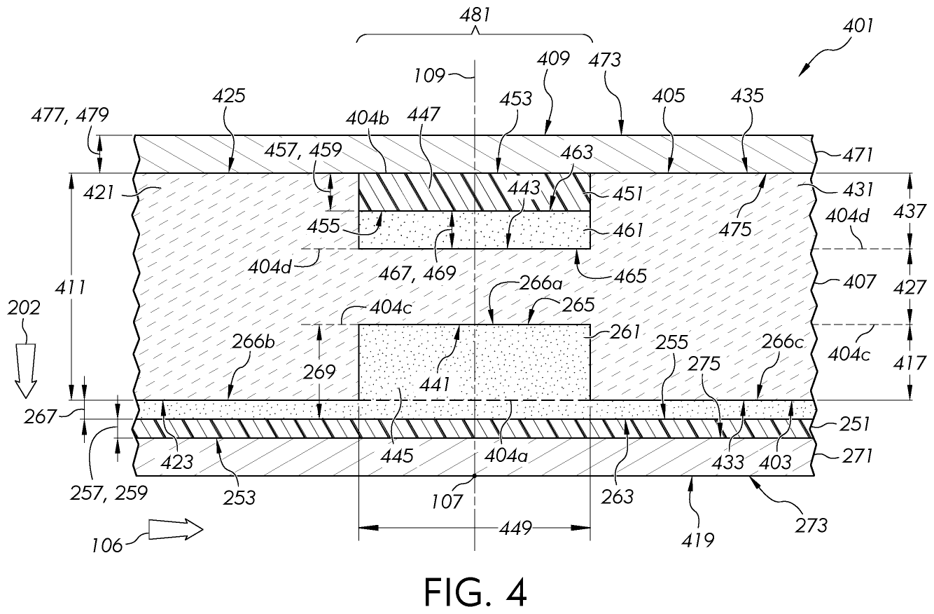

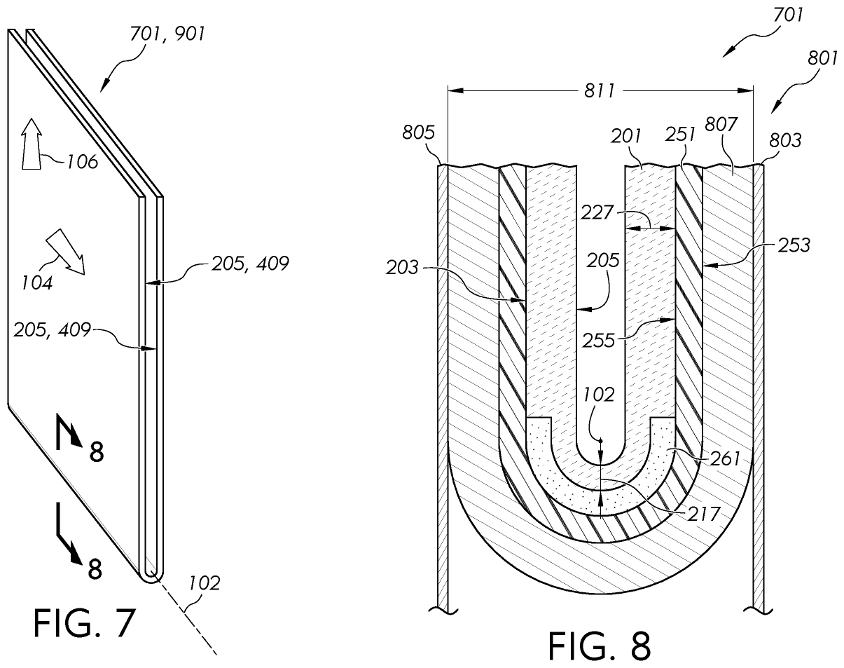

FIGS. 1-6 schematically illustrate example aspects of foldable apparatus 101, 301, 401, 501, and 601 in accordance with aspects of the disclosure in an unfolded (e.g., flat) configuration while FIGS. 7-9 demonstrate a foldable apparatus 701 and 901 in accordance with aspects of the disclosure in a folded configuration. As shown in FIGS. 2-6, the foldable apparatus 101, 301, 401, 501, and 601 can comprise a first adhesive layer 261 positioned between a first polymer-based portion 251 and a foldable substrate 201 or 407. In aspects, as shown in FIGS. 2-6, the foldable apparatus 101, 301, 401, 501, and 601 can comprise a first recess 219 or 445 and the foldable apparatus 401, 501, and 601, as shown in FIGS. 4-6, can further comprise a second recess 447 opposite the first recess 445. In aspects, as shown in FIGS. 3 and 5-6, the foldable apparatus 301, 501, and 601 can comprise a display device 307 or, as shown in FIGS. 2 and 4, the foldable apparatus 101 and 401 can comprise a release liner 271, although a cover substrate (e.g., glass-based substrate, ceramic-based substrate) can be provided in place of or in addition to a display device or a release liner in further aspects.

As shown in FIGS. 2-6, the foldable apparatus 101, 301, 401, 501, and 601 can comprise the foldable substrate 201 or 407. In further aspects, the foldable substrate 201 or 407 can comprise a glass-based substrate and/or a ceramic-based substrate having a pencil hardness of 8H or more, for example, 9H or more. As used herein, pencil hardness is measured using ASTM D 3363-20 with standard lead graded pencils. Providing a glass-based substrate and/or a ceramic-based substrate can enhance puncture resistance and/or impact resistance.

As used herein, “glass-based” includes both glasses and glass-ceramics, wherein glass-ceramics have one or more crystalline phases and an amorphous, residual glass phase. A glass-based material (e.g., glass-based substrate) can comprise an amorphous material (e.g., glass) and optionally one or more crystalline materials (e.g., ceramic). Amorphous materials and glass-based materials can be strengthened. As used herein, the term “strengthened” may refer to a material that has been chemically strengthened, for example, through ion-exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing alumino phosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of about 10 mol % or less, wherein R₂O comprises Li₂O Na₂O, K₂O or the more expansive list provided below). In one or more aspects, a glass-based material may comprise, in mole percent (mol %): SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have about 1% to about 99% crystallinity. Examples of suitable glass-ceramics can include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates can be strengthened using chemical strengthening processes. In one or more aspects, MAS-System glass-ceramic substrates can be strengthened in Li₂SO₄ molten salt, whereby an exchange of 2Li⁺ for Mg²⁺ can occur.

As used herein, “ceramic-based” includes both ceramics and glass-ceramics, wherein glass-ceramics have one or more crystalline phases and an amorphous, residual glass phase. Ceramic-based materials can be strengthened (e.g., chemically strengthened). In aspects, a ceramic-based material can be formed by heating a glass-based material to form ceramic (e.g., crystalline) portions. In further aspects, ceramic-based materials can comprise one or more nucleating agents that can facilitate the formation of crystalline phase(s). In aspects, the ceramic-based materials can comprise one or more oxides, nitrides, oxynitrides, carbides, borides, and/or silicides. Example aspects of ceramic oxides include zirconia (ZrO₂), zircon (ZrSiO₄), an alkali metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example aspects of carbides and carbon-containing ceramics include silicon carbide (SiC), tungsten carbide (WC), an iron carbide, boron carbide (B₄C), alkali metal carbides (e.g., lithium carbide (Li₄C₃)), alkali earth metal carbides (e.g., magnesium carbide (Mg₂C₃)), and graphite. Example aspects of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example aspects of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali metal silicide (e.g., magnesium silicide (Mg₂Si)), hafnium disilicide (HfSi₂), and platinum silicide (PtSi).

Throughout the disclosure, an elastic modulus (e.g., Young's modulus) of the foldable substrate 201 or 407 is measured using indentation methods in accordance with ASTM E2546-15. In aspects, the foldable substrate 201 or 407 can comprise an elastic modulus of about 10 GigaPascals (GPa) or more, about 50 GPa or more, about 60 GPa or more, about 70 GPa or more, about 100 GPa or less, or about 80 or less. In aspects, the foldable substrate 201 or 407 can comprise an elastic modulus in a range from about 10 GPa to about 100 GPa, from about 50 GPa to about 100 GPa, from about 60 GPa to about 80 GPa, from about 70 GPa ta about 80 GPa, or any range or subrange therebetween.

As shown in FIGS. 2-6, the foldable substrate 201 or 407 can comprise a first major surface 203 or 403 and a second major surface 205 or 405 opposite the first major surface 203 or 403. In aspects, as shown, the first major surface 203 or 403 can extend along a first plane 204a or 404a, and/or the second major surface 205 or 405 can extend along a second plane 204b or 404b. In aspects, as shown, the second plane 204b or 404b can be parallel to the first plane 204a or 404a. As used herein, a substrate thickness 227 or 411 is defined between the first major surface 203 or 403 and the second major surface 205 or 405 as an average distance therebetween. Throughout the disclosure, the first major surface and the second major surface do not include portions of the foldable substrate in the central portion (e.g., central portion 281 or 481) discussed below. In aspects, the substrate thickness 227 or 411 can be equal to a distance between the first plane 204a or 404a and the second plane 204b or 404b. In aspects, the substrate thickness 227 or 411 extends between the first major surface 203 or 403 and the second major surface 205 or 405 in a direction 202. In further aspects, the direction 202 can be perpendicular to the first major surface 203. In aspects, the substrate thickness 227 or 411 can be about 25 micrometers (μm) or more, about 60 μm or more, about 80 μm or more, about 100 μm or more, about 125 μm or more, about 150 μm or more, about 3 millimeters (mm) or less, about 2 mm or less, about 1 mm or less, about 800 μm or less, about 500 μm or less, about 300 μm or less, about 200 μm or less, about 180 μm or less, or about 160 μm or less. In aspects, the substrate thickness 227 or 411 can be in a range from about 25 μm to about 3 mm, from about 25 μm to about 2 mm, from about 60 μm to about 2 mm, from about 80 μm to about 2 mm, from about 100 μm to about 2 mm, from about 100 μm to about 1 mm, from about 100 μm to about 800 μm, from about 100 μm to about 500 μm, from about 125 μm to about 500 μm, from about 125 μm to about 300 μm, from about 125 μm to about 200 μm, from about 150 μm to about 200 μm, from about 150 μm to about 160 μm, or any range or subrange therebetween.

As shown in FIGS. 2-6, the foldable substrate 201 or 407 can comprise a first portion 221 or 421 and a second portion 231 or 431. In aspects, as shown, the first portion 221 or 421 can comprise a first surface area 223 or 423 comprising a portion of the first major surface 203 or 403 and a second surface area 225 or 425 comprising a portion of the second major surface 205 or 405 opposite the first surface area 223 or 423. In further aspects, as shown, an average distance between the first surface area 223 or 423 and the second surface area 225 or 425 can be substantially equal to the substrate thickness 227 or 411. In aspects, as shown, the second portion 231 or 431 can comprise a third surface area 233 or 433 comprising a portion of the first major surface 203 or 403 and a fourth surface area 235 or 435 comprising a portion of the second major surface 205 or 405 opposite the third surface area 233 or 433. In further aspects, as shown, an average distance between the third surface area 233 or 433 and the fourth surface area 235 or 435 can be substantially equal to the substrate thickness 227 or 411.

As shown in FIGS. 2-6, a central portion 281 or 481 of the foldable substrate 201 or 407 can be positioned between the first portion 221 or 421 and the second portion 231 or 431. In further aspects, as shown, the central portion 281 or 481 can comprise a first central surface area 211 or 441 positioned between the first surface area 223 or 423 and the third surface area 233 or 433. In even further aspects, as shown, the first central surface area 211 or 441 can extend along a third plane 204c or 404c. In further aspects, as shown, the central portion 281 or 481 can comprise a second central surface area 213 or 443 opposite the first central surface area 211 or 441. As used herein, a central thickness 217 or 427 is defined between the first central surface area 211 or 441 and the second central surface area 213 or 443 as an average distance therebetween in the direction 202 of the substrate thickness 227 or 411. In further aspects, the central thickness 217 or 427 can be about 0.5% or more, about 1% or more, about 2% or more, about 5% or more, about 13% or less, about 10% or less, or about 5% or less of the substrate thickness 227 or 411. In aspects, the central thickness 217 or 427 as a percentage of the substrate thickness 227 or 411 can be in a range from about 0.5% to about 13%, from about 0.5% to about 10%, from about 1% to about 10%, from about 2% to about 10%, from about 5% to about 10%, or any range or subrange therebetween. In further aspects, the central thickness 217 or 427 can be within one or more of the ranges for the substrate thickness while being less than the substrate thickness. In further aspects, the central thickness 217 or 427 can be about 10 μm or more, about 25 μm or more, about 80 μm or more, about 220 μm or less, about 125 μm or less, about 100 μm or less, about 80 μm or less, about 60 μm or less, or about 40 μm or less. In even further aspects, the central thickness 217 or 427 can be in a range from about 10 μm to about 220 μm, from about 10 μm to about 125 μm, from about 10 μm to about 100 μm, from about 10 μm to about 80 μm, from about 25 μm to about 80 μm, from about 25 μm to about 60 μm, from about 25 μm to about 40 μm, or any range or subrange therebetween.

In aspects, as shown in FIGS. 2-6, the central thickness 217 or 427 is less than the substrate thickness 227 or 411 to provide the first recess 219 or 445 that can be defined between the first plane 204a or 404a and the first central surface area 211 or 441. In further aspects, as shown, the first central surface area 211 or 441 can be recessed from the first plane 204a or 404a (e.g., first major surface 203 or 403) by a first distance 229 or 417. In even further aspects, the first distance 229 or 417, as a percentage of the substrate thickness 227 or 411, can be about 1% or more, about 5% or more, about 10% or more, about 15% or more, about 20% or more, about 25% or more, about 30% or more, about 75% or less, about 60% or less, about 45% or less, about 40% or less, about 35% or less, about 20% or less, or about 15% or less. In even further aspects, the first distance 229 or 417, as a percentage of the substrate thickness 227 or 411, can be in a range from about 1% to about 75%, from about 1% to about 60%, from about 5% to about 45%, from about 5% to about 35%, from about 5% to about 20%, from about 5% to about 15%, from about 10% to about 15%, or any range or subrange therebetween. In even further aspects, the first distance 229 or 417, as a percentage of the substrate thickness 227 or 411, can be in a range from about 20% to about 45%, from about 25% to about 45%, from about 25% to about 40%, from about 30% to about 40%, from about 30% to about 35%, or any range or subrange therebetween.

In aspects, as shown in FIGS. 2-3, the second major surface 205 can be continuous with the second central surface area 213. As used herein, “continuous” means that the second central surface area extends as a continuation of the second major surface to form a monolithic surface. In aspects, as shown in FIGS. 4-6, the second central surface area 443 can be recessed from the second major surface 405 by a second distance 437. In aspects, the second distance 437, as a percentage of the substrate thickness 411, can be within a range from about 1% to about 45%, from about 1% to about 40%, from about 1% to about 35%, from about 1% to about 20%, from about 5% to about 20%, from about 5% to about 15%, from about 10% to about 15%, or any range or subrange therebetween. In further aspects, as shown, the first distance 417 can be substantially equal to the second distance 437. In further aspects, as shown, the second recess 447 can be defined between the second plane 404b and the second central surface area 443. In aspects, as shown in FIGS. 2-3, the second central surface area 213 can extend along a second plane 204b.

In aspects, as shown in FIGS. 2-6, a transition between the first central surface area 211 or 441 and the first surface area 223 or 423 and/or the third surface area 233 or 433 can be substantially abrupt (e.g., sufficiently narrow to resemble straight sides substantially perpendicular to the first plane 204a or 404a and/or third plane 204c or 404c). In aspects, as shown in FIGS. 4-6, a transition between the second central surface area 443 and the second surface area 425 and/or the fourth surface area 435 can be substantially abrupt (e.g., sufficiently narrow to resemble straight sides substantially perpendicular to the second plane 404b and/or fourth plane 404d). In aspects, as not shown, the foldable substrate can comprise a gradual (e.g., linear, curved, curvilinear) transition between the first central surface area and the first surface area and/or the third surface area. In aspects, although not shown, the foldable substrate can comprise a gradual (e.g., linear, curved, curvilinear) transition between the second central surface area and the second surface area and/or the fourth surface area when the second central surface area is recessed from the second major surface.

In aspects, as shown in FIGS. 2-6, a width 252 or 449 of the central portion 281 or 481 of the foldable substrate 201 or 407 can be defined between the first portion 221 or 421 and the second portion 231 or 431 in a direction 106 (e.g., a direction of a length 105, discussed below) perpendicular to the direction 202 of the substrate thickness 227 or 411. In aspects, the width 252 or 449 of the central portion 281 or 481 can be about 2.2 mm or more, about 4.4 mm or more, about 8 mm or more, about 10 mm or more, about 12 mm or more, about 15 mm or more, about 60 mm or less, about 50 mm or less, about 40 mm or less, about 30 mm, or less, or about 25 mm or less, about 20 mm or less, or about 17 mm or less. In aspects, the width 252 or 449 of the central portion 281 or 481 can be in a range from about 2.2 mm to about 60 mm, from about 4.4 mm to about 50 mm, from about 8 mm to about 40 mm, from about 10 mm to about 30 mm, from about 10 mm to about 25 mm, from about 12 mm to about 25 mm, from about 12 mm to about 20 mm, from about 15 mm to about 20 mm, from about 15 mm to about 17 mm, or any range of subrange therebetween. By providing a width within the above-noted ranges for the central portion (e.g., between the first portion and the second portion), folding of the foldable apparatus without failure and/or reduced bend force can be facilitated.

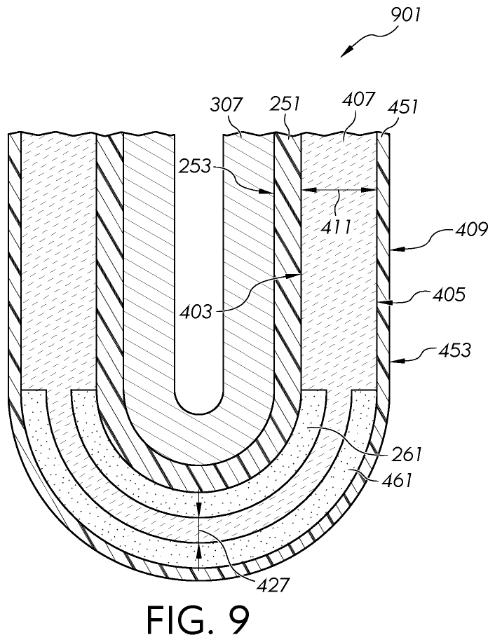

In aspects, the foldable substrate 201 or 407 can comprise a first portion comprising a glass-based substrate and/or ceramic-based substrate where one or more portions of the foldable substrate can comprise a compressive stress region. In aspects, the compressive stress region can be created by chemically strengthening the foldable substrate. Chemically strengthening can comprise an ion exchange process, where ions in a surface layer are replaced by—or exchanged with—larger ions having the same valence or oxidation state. Without wishing to be bound by theory, chemically strengthening the foldable substrate can enable small (e.g., smaller than about 10 mm or less) bend radii because the compressive stress from the chemical strengthening can counteract the bend-induced tensile stress on the outermost surface of the foldable substrate (e.g., first major surface 203 in FIG. 8, second major surface 405 in FIG. 9). A compressive stress region can extend into a portion of the foldable substrate for a depth called the depth of compression. As used herein, depth of compression means the depth at which the stress in the chemically strengthened substrates described herein changes from compressive stress to tensile stress. Depth of compression can be measured by a surface stress meter or a scattered light polariscope (SCALP) depending on the ion exchange treatment and the thickness of the article being measured. Where the stress in the substrate is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 75 μm, SCALP is used to measure the depth of compression and central tension (CT). Where the stress in the substrate is generated by exchanging both potassium and sodium ions into the glass, and the article being measured is thicker than about 75 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF) method also may be used to derive a graphical representation of the stress profile. The RNF method is described in U.S. Pat. No. 8,854,623, entitled “Systems and methods for measuring a profile characteristic of a glass sample”, which is incorporated herein by reference in its entirety. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate (e.g., sodium, potassium). Through the disclosure, when the central tension cannot be measured directly by SCALP (as when the article being measured is thinner than about 75 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 or 421 can comprise a first compressive stress region at the first surface area 223 or 423 that can extend to a first depth of compression from the first surface area 223 or 423. In aspects, the first portion 221 or 421 can comprise a second compressive stress region at the second surface area 225 or 425 that can extend to a second depth of compression from the second surface area 225 or 425. In aspects, the first depth of compression and/or the second depth of compression as a percentage of the substrate thickness 227 or 411 can be about 1% or more, about 5% or more, about 10% or more, about 30% or less, about 25% or less, or about 20% or less. In aspects, the first depth of compression and/or the second depth of compression as a percentage of the substrate thickness 227 or 411 can be in a range from about 1% to about 30%, from about 5% to about 30%, from about 10% to about 30%, from about 10% to about 25%, from about 10% to about 20%, or any range or subrange therebetween. In further aspects, the first depth of compression can be substantially equal to the second depth of compression. In further aspects, the first depth of compression and/or the second depth of compression can be about 1 μm or more, about 10 μm or more, about 30 μm or more, about 50 μm or more, about 200 μm or less, about 150 μm or less, about 100 μm or less, or about 60 μm or less. In further aspects, the first depth of compression and/or the second depth of compression can be in a range from about 1 μm to about 200 μm, from about 10 μm to about 150 μm, from about 30 μm to about 100 μm, from about 50 μm to about 60 μm, or any range or subrange therebetween. In aspects, the first compressive stress region can comprise a first maximum compressive stress. In aspects, the second compressive stress region can comprise a second maximum compressive stress. In further aspects, the first maximum compressive stress and/or the second maximum compressive stress can be about 100 MegaPascals (MPa) or more, about 300 MPa or more, about 400 MPa or more, about 600 MPa or more, about 700 MPa or more, about 1,500 MPa or less, about 1,200 MPa or less, about 1,000 MPa or less, or about 800 MPa or less. In further aspects, the first maximum compressive stress and/or the second maximum compressive stress can be in a range from about 100 MPa to about 1,500 MPa, from about 100 MPa to about 1,200 MPa, from about 400 MPa to about 1,200 MPa, from about 400 MPa to about 1,000 MPa, from about 500 MPa to about 1,000 MPa, from about 600 MPa to about 1,000 MPa, from about 700 MPa to about 1,000 MPa, from about 700 MPa to about 800 MPa, or any range or subrange therebetween. By providing a first portion comprising a first glass-based and/or ceramic-based portion comprising a first depth of compression and/or a second depth of compression, good impact and/or puncture resistance can be enabled.

In aspects, the second portion 231 or 431 can comprise a third compressive stress region at the third surface area 233 or 433 that can extend to a third depth of compression from the third surface area 233 or 433. In aspects, the second portion 231 or 431 can comprise a fourth compressive stress region at the fourth surface area 235 or 435 that can extend to a fourth depth of compression from the fourth surface area 235 or 435. In aspects, the third depth of compression and/or the fourth depth of compression either as a percentage of the substrate thickness 227 or 411 or as an absolute depth can be within one or more of the ranges discussed above for the first depth of compression. In further aspects, the third depth of compression can be substantially equal to the fourth depth of compression. In further aspects, the first depth of compression can be substantially equal to the third depth of compression, and/or the second depth of compression can be substantially equal to the fourth depth of compression. In aspects, the third compressive stress region can comprise a third maximum compressive stress. In aspects, the fourth compressive stress region can comprise a fourth maximum compressive stress. In further aspects, the third maximum compressive stress and/or the fourth maximum compressive stress can be within one or more of the ranges discussed above for the first maximum compressive stress. By providing a second portion comprising a second glass-based and/or ceramic-based portion comprising a third depth of compression and/or a fourth depth of compression, good impact and/or puncture resistance can be enabled.

In aspects, the central portion 281 or 481 can comprise a first central compressive stress region at the first central surface area 211 or 441 that can extend to a first central depth of compression from the first central surface area 211 or 441. In aspects, the central portion 281 or 481 can comprise a second central compressive stress region at the second central surface area 213 or 443 that can extend to a second central depth of compression from the second central surface area 213 or 443. In aspects, the first central depth of compression and/or the second central depth of compression, as a percentage of the central thickness 217 or 427, can be within one or more of the ranges for the first depth of compression, as a percentage of the substrate thickness 227 or 411, discussed above. In further aspects, the first central depth of compression can be substantially equal to the second central depth of compression. In further aspects, the first central depth of compression and/or the second central depth of compression, as a percentage of the central thickness 217 or 427, can be less than a first depth of compression, second depth of compression, third depth of compression, and/or fourth depth of compression, as a percentage of the substrate thickness 227 or 411.

As shown in FIGS. 2-6, the first adhesive layer 261 can be disposed in the first recess 219 or 445. In aspects, the first adhesive layer 261 can be at least partially positioned in the first recess 219 or 445. In further aspects, as shown in FIGS. 2-3 and 5-6, the first adhesive layer 261 can be completely within the first recess 219 or 445. In aspects, as shown in FIGS. 2-6, the first adhesive layer 261 can comprise a first contact surface 263 and a second contact surface 265 opposite the first contact surface 263. In further aspects, the second contact surface 265 can face and/or contact the first central surface area 211 or 441. In further aspects, as shown in FIG. 4, the second contact surface 265 can comprise a first portion 266a facing and/or contacting the first central surface area 441, a second portion 266b facing and/or contacting the first surface area 423, and/or a third portion 266c facing and/or contacting the third surface area 433. As used herein, a maximum first adhesive thickness 269 is defined as a maximum distance between the first contact surface 263 and the second contact surface 265 in the direction 202 of the substrate thickness 227 or 411. As used herein, a minimum first adhesive thickness 267 is defined as a minimum distance between the first contact surface 263 and the second contact surface 265 in the direction 202 of the substrate thickness 227 or 411. In further aspects, as shown in FIGS. 2-3 and 5-6, the maximum first adhesive thickness 269 and the minimum first adhesive thickness 267 can be substantially equal, for example, when the first adhesive layer is completely within the first recess 219 or 445 and/or the first adhesive layer does not extend beyond the central portion 281 or 481. In further aspects, as shown in FIG. 4, the minimum first adhesive thickness 267 can be different from the maximum first adhesive thickness 269, for example, when the first adhesive layer extends beyond the central portion 281 or 481. In even further aspects, a difference between the maximum first adhesive thickness 269 and the minimum first adhesive thickness 267 can be substantially equal to the first distance 417 that the first central surface area 441 is recessed from the first major surface 403. In further aspects, the maximum first adhesive thickness 269 can be about 5 μm or more, about 10 μm or more, about 15 μm or more, about 20 μm or more, about 500 μm or less, 200 μm or less, about 100 μm or less, about 60 μm or less, about 40 μm or less, or about 30 μm or less. In further aspects, the maximum first adhesive thickness 269 can be in a range from about 5 μm to about 500 μm, from about 5 μm to about 200 μm, from about 5 μm to about 100 μm, from about 10 μm to about 100 μm, from about 15 μm to about 100 μm, from about 15 μm to about 60 μm, from about 20 μm to about 60 μm, from about 20 μm to about 40 μm, from about 20 μm to about 30 μm, or any range or subrange therebetween. In further aspects, when the maximum first adhesive thickness 269 is different than the minimum first adhesive thickness 267, the minimum first adhesive thickness 267 can be about 1 μm or more, about 5 μm or more, about 40 μm or less, about 20 μm or less, or about 10 μm or less. In further aspects, when the maximum first adhesive thickness 269 is different than the minimum first adhesive thickness 267, the minimum first adhesive thickness 267 can be in a range from about 1 μm to about 40 μm, from about 5 μm to about 20 μm, from about 5 μm to about 10 μm, or any range or subrange therebetween. Providing a first adhesive thickness of about 5 μm or more can be sufficient to provide a neutral plane within the first adhesive portion, which can provide further benefits discussed below.

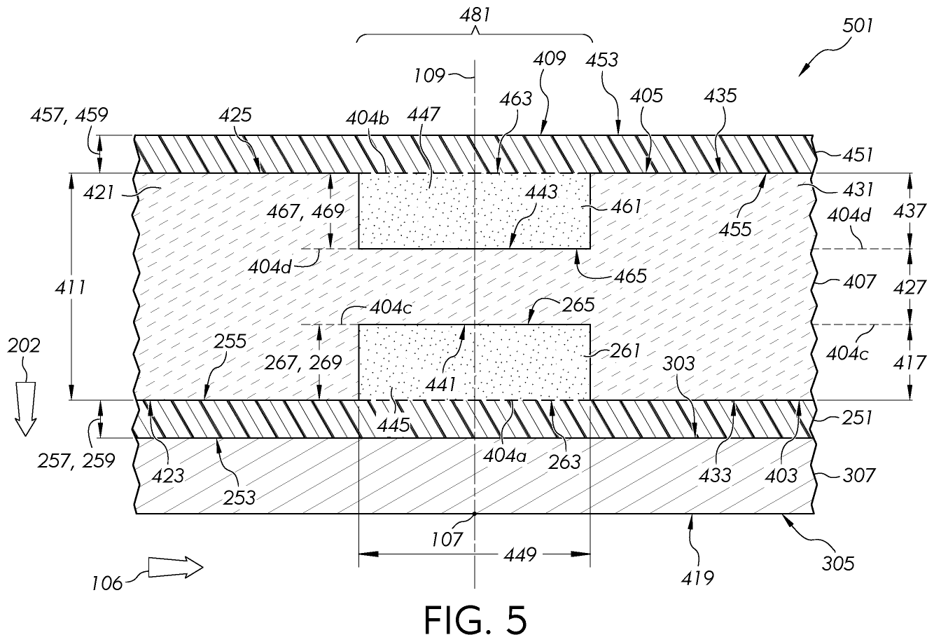

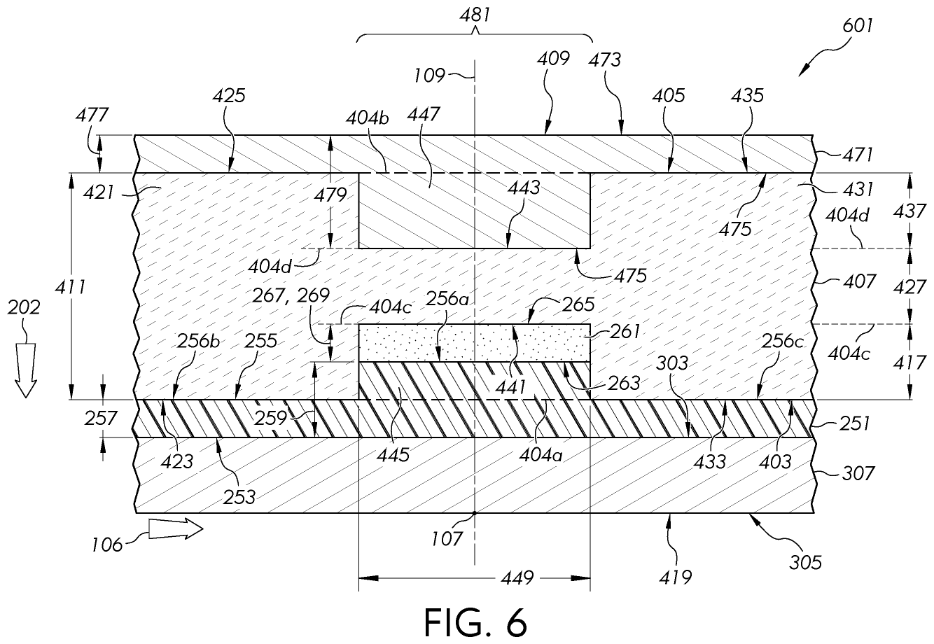

In further aspects, as shown in FIGS. 2 and 6, the maximum first adhesive thickness 269 and the minimum first adhesive thickness 267 can be less than the first distance 229 or 417 that the first central surface area 211 or 441 is recessed from the first major surface 203 or 403. In even further aspects, the maximum first adhesive thickness 269 can be less than the first distance 229 or 417 by about 10 μm or more, about 15 μm or more, or about 20 μm or more. In further aspects, as shown in FIGS. 3 and 5, the maximum first adhesive thickness 269 can be substantially equal to the first distance 229 or 417 that the first central surface area 211 or 441 is recessed from the first major surface 203 or 403. In even further aspects, as shown in FIGS. 3 and 5, the first contact surface 263 can extend along a common plane (e.g., first plane 204a or 404a) with the first major surface 203 or 403. In further aspects, as shown in FIG. 4, the minimum first adhesive thickness 267 can be less than the maximum first adhesive thickness 269 by about 10 μm or more, about 15 μm or more, or about 20 μm or more. In further aspects, as shown in FIG. 4, the maximum first adhesive thickness 269 can be greater than the first distance 417 that the first central surface area 441 is recessed from the first major surface 403. In even further aspects, the maximum first adhesive thickness 269 can be greater than the first distance 417 by about 1 μm or more, about 5 μm or more, about 10 μm or more, about 40 μm or less, about 20 μm or less, or about 10 μm or less. In even further aspects, an amount that the maximum first adhesive thickness 269 is greater than the first distance 417 can be in a range from about 1 μm to about 40 μm, from about 5 μm to about 40 μm, from about 5 μm to about 20 μm, from about 5 μm to about 10 μm, or any range or subrange therebetween.

Throughout the disclosure, a tensile strength, ultimate elongation (e.g., strain at failure), yield point of a polymeric material (e.g., adhesive, polymer-based portion), and strain at the yield point (i.e., strain at yield) is determined using ASTM D638 using a tensile testing machine, for example, an Instron 3400 or Instron 6800, at 23° C. and 50% relative humidity with a type I dogbone shaped sample. In aspects, the first adhesive layer 261 can comprise an elastic modulus (i.e., Young's modulus). As used herein, an elastic modulus (i.e., Young's modulus) is a ratio of uniaxial stress to strain. Throughout the disclosure, the elastic modulus and/or a Poisson's ratio is measured using ISO 527-1:2019. In aspects, the elastic modulus of the first adhesive layer 261 can be about 0.001 MPa or more, about 0.005 MPa or more, about 0.01 MPa or more, about 0.02 MPa or more, about 0.05 MPa or more, about 0.08 MPa or more, about 0.4 MPa or less, about 0.3 MPa or less, about 0.2 MPa or less, or about 0.1 MPa or less. In aspects, the elastic modulus of the first adhesive layer 261 can be in a range from about 0.001 MPa to about 0.4 MPa, from about 0.005 MPa to about 0.4 MPa, from about 0.005 MPa to about 0.3 MPa, from about 0.01 MPa to about 0.3 MPa, from about 0.02 MPa to about 0.3 MPa, from about 0.02 MPa to about 0.2 MPa, from about 0.05 MPa to about 0.2 MPa, from about 0.05 MPa to about 0.1 MPa, from about 0.08 MPa to about 0.1 MPa, or any range or subrange therebetween. Providing an elastic modulus of the first adhesive layer within one or more of the above-mentioned ranges can be sufficient to provide a neutral plane within the first adhesive portion, which can provide further benefits discussed below.

As used herein, Poisson's ratio is a ratio of a lateral expansion resulting from an axial compression to the axial contraction from the axial compression. Without wishing to be bound by theory, a Poisson's ratio of 0.5 corresponds to an incompressible isotropic material, meaning that the volume of the material does not change as a result of axial compression. In aspects, the first adhesive layer 261 can comprise a Poisson's ratio of about 0.20 or more, about 0.30 or more, about 0.40 or more, about 0.45 or more, about 0.49 or more, about 0.495 or more, about 0.499 or more, or about 0.50 or less. In aspects, the first adhesive layer 261 can comprise a Poisson's ratio in a range from about 0.20 to about 0.50, from about 0.30 to about 0.50, from about 0.40 to about 0.50, from about 0.45 to about 0.50, from about 0.49 to about 0.50, from about 0.495 to about 0.50, from about 0.499 to about 0.50, or any range or subrange therebetween. Providing a second portion comprising a Poisson's ratio near 0.5 can reduce bend-induced volume changes, which can reduce the incidence of optical distortions and/or bend-induced mechanical instabilities.

In aspects, the first adhesive layer 261 can comprise an optically clear adhesive and/or a pressure-sensitive adhesive. In further aspects, the adhesive can comprise an optically clear adhesive comprising a polymer (e.g., optically transparent polymer). Exemplary aspects of optically clear adhesives can comprise, but are not limited to acrylic adhesives (e.g., 3M 8212 adhesive), an optically transparent liquid adhesive (e.g., a LOCTITE optically transparent liquid adhesive), and transparent acrylics, epoxies, silicones, and polyurethanes. In aspects, the first adhesive layer 261 can comprise one or more of a silicone-based polymer, an acrylate-based polymer, an epoxy-based polymer, a thiol-containing polymer, or a polyurethane. In even further aspects, the silicone-based polymer can comprise a silicone elastomer. Exemplary aspects of a silicone elastomer include PP2-OE50 available from Gelest and LS 8941 available from NuSil. In even further aspects, the first adhesive layer 261 can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the first material can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). In aspects, the first adhesive layer 261 can comprise a sol-gel material. Example aspects of polyurethanes comprise thermoset polyurethanes, for example, Dispurez 102 available from Incorez and thermoplastic polyurethanes, for example, KrystalFlex PE505 available from Huntsman. In even further aspects, the first adhesive layer 261 can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the first adhesive layer 261 comprises Eleglass W802-GL044 available from Axalta with from 1 wt % to 2 wt % cross-linker.

In aspects, the first adhesive layer 261 can comprise a polymer-based material comprising a glass-transition (Tg) temperature. As used herein, the glass transition temperature, the elastic modulus at a range of temperatures, and the elastic modulus at a glassy plateau are measured using Dynamic Mechanical Analysis (DMA) with an instrument, for example, the DMA 850 from TA Instruments. In further aspects, the glass transition temperature of the polymer-based material can be about 0° C. or less, about −20° C. or less, or about −40° C. or less. In further aspects, the glass transition temperature of the polymer-based portion can be in a range from about −200° C. to about 0° C., from about −160° C. to about 0° C., from about −100° C. to about 0° C., from about −100° C. to about −20° C., from about −80° C. to about −20° C., from about −80° C. to about −40° C., or any range or subrange therebetween. In further aspects, the glass transition temperature of the polymer-based material can be about 40° C. or more, about 50° C. or more, about 60° C. or more, or about 70° C. or more. In further aspects, the glass transition temperature of the polymer-based portion can be in a range from about 40° C. to about 250° C., from about 50° C. to about 220° C., from about 60° C. to about 200° C., from about 60° C. to about 180° C., from about 60° C. to about 150° C., from about 60° C. to about 120° C., from about 70° C. to about 100° C., or any range or subrange therebetween. Providing a first adhesive layer with a glass transition temperature outside of an operating range (e.g., from about 0° C. to about 40° C., from about −20° C. to about 60° C.) of a foldable apparatus can enable the foldable apparatus to have consistent properties across the operating range.

In aspects, the first adhesive layer 261 can remain within an elastic deformation regime. In aspects, the first adhesive layer 261 can remain within an elastic deformation regime when the foldable apparatus achieves a parallel plate distance of 3 mm or less (discussed below). As discussed above, strain at yield is determined according to ASTM D638 using a tensile testing machine, for example, an Instron 3400 or Instron 6800, at 23° C. and 50% relative humidity with a type I dogbone shaped sample. In aspects, the first adhesive layer 261 can comprise a strain at yield of about 10% or more, about 50% or more, about 100% or more, about 150% or more, or about 200% or more. In aspects, the first adhesive layer 261 can comprise a strain at yield in a range from about 10% to about 10,000%, from about 50% to about 5,000%, from about 100% to about 1,000%, from about 100% to about 500%, from about 100% to about 300%, from about 100% to about 200%, from about 150% to about 1,000%, from about 150% to about 500%, from about 200% to about 500%, or any range or subrange therebetween. In aspects, the second material can comprise one or more of a polyamide, LDPE, HDPE, PTFE, perfluoroalkoxyethylene, PVF, ETFE, polybutadiene rubber, nitrile rubber, and styrene-butadiene rubber.

In aspects, the first adhesive layer 261 can comprise particles and/or nanoparticles. In further aspects, the second portion can comprise one or more types of nanoparticles, for example, silica, alumina, kaolin, and/or hydroxyapatite. In further aspects, the second portion can comprise one or more types of particles, for example, copper oxide, beta-quartz, a tungstate, a vanadate, a pyrophosphate, and/or a nickel-titanium alloy. In further aspects, the second portion can comprise a low coefficient of thermal expansion (CTE) or a negative coefficient of thermal expansion. As used herein, a coefficient of thermal expansion is measured in accordance with ASTM E289-17 using a Picoscale Michelson Interferometer between −20° C. and 40° C. In even further aspects, the first adhesive layer 261 can comprise a CTE of about −20×10^{-7 1}/° C. or more, about −10×10^{-7 1}/° C. or more, about −5×10^{-7 1}/° C. or more, about −2×10^{-7 1}/° C. or more, about 10×10^{-7 1}/° C. or less, about 5×10^{-7 1}/° C. or less, about 2×10^{-7 1}/° C. or less, about 1×10^{-7 1}/° C. or less, or 0 1/° C. or less. In even further aspects, the first adhesive layer 261 can comprise a CTE in a range from about −20×10^{-7 1}/° C. to about 10×10^{-7 1}/° C., from about −20×10^{-7 1}/° C. to about 5×10^{-7 1}/° C., from about −10×10^{-7 1}/° C. to about −5×10^{-7 1}/° C., from about −10×10^{-7 1}/° C. to about 2×10^{-7 1}/° C., from about −10×10^{-7 1}/° C. to 0 1/° C., from about −5×10^{-7 1}/° C. to 0 1/° C., from about −2×10^{-7 1}/° C. to about 0 1/° C., or any range or subrange therebetween.

Throughout the disclosure, a flexural rigidity of a material is the product of the elastic modulus of the material and a cube of the thickness of the material divided by 12 times the quantity of 1 minus a square of the Poisson's ratio of the material. In aspects, the first adhesive layer 261 can comprise a flexural rigidity of about 10⁻¹² Pa m³ or more, about 10⁻¹¹ Pa m³ or more, about 10⁻¹⁰ Pa m³ or more, about 10⁻⁷ Pa m³ or less, about 10⁻⁸ Pa m³ or less, or about 4×10⁻⁸ Pa m³ or less. In aspects, the first adhesive layer 261 can comprise a flexural rigidity in a range from about 10⁻¹² Pa m³ to about 10⁻⁷ Pa m³, from about 10⁻¹¹ Pa m³ to about 10⁻⁷ Pa m³, from about 10⁻¹¹ Pa m³ to about 10⁻⁸ Pa m³, from about 10⁻¹¹ Pa m³ to about 4×10⁻⁸ Pa m³, from about 10⁻¹⁰ Pa m³ to about 4×10⁻⁸ Pa m³, or any range or subrange therebetween. Providing the first adhesive layer 261 comprising a low (e.g., about 10⁻⁷ Pa m³ or less) flexural rigidity can reduce bend-induced stresses in adjacent first portions, which can reduce the incidence of bend-induced mechanical instabilities.

As shown in FIGS. 2-6, the first polymer-based portion 251 can be disposed on the first adhesive layer 261. In aspects, as shown in FIGS. 2 and 6, the first polymer-based portion 251 can be at least partially positioned in the first recess 219 or 445. In aspects, as shown in FIGS. 3-5, the first polymer-based portion 251 may not be positioned in the first recess 219 or 445. In aspects, as shown in FIGS. 2-6, the first adhesive layer 261 can be positioned between the first polymer-based portion 251 and the first central surface area 211 or 441. In further aspects, as shown in FIG. 4, the first adhesive layer 261 can be positioned between the first polymer-based portion 251 and the first portion 421 (e.g., first surface area 423) and/or between the first polymer-based portion 251 and the second portion 431 (e.g., third surface area 433).

In aspects, as shown in FIGS. 2-6, the first polymer-based portion 251 can comprise a third contact surface 253 and a fourth contact surface 255 opposite the third contact surface 253. In further aspects, as shown, the fourth contact surface 255 of the first polymer-based portion 251 can face and/or contact the first contact surface 263 of the first adhesive layer 261, and the first contact surface 263 of the first adhesive layer 261 can face and/or contact the fourth contact surface 255 of the first polymer-based portion 251. In further aspects, as shown, the fourth contact surface 255 can face the first central surface area 211 or 441, the first surface area 223 or 423, and/or the third surface area 233 or 433. In even further aspects, as shown in FIGS. 2-3 and 5-6, the fourth contact surface 255 can contact the first surface area 223 or 423 and/or the third surface area 233 or 433. In aspects, as shown in FIGS. 2 and 6, the fourth contact surface 255 can comprise a first portion 256a in the central portion 281 or 481 within the first recess 219 or 445, a second portion 256b facing the first surface area 223 or 423, and/or a third portion 256c facing the third surface area 233 or 433. Providing the first adhesive layer positioned between the first central surface area and the first polymer-based portion can provide a neutral plane within the first adhesive portion, which can provide further benefits discussed below.

As used herein, a maximum first polymer-based thickness 259 is defined as a maximum distance between the third contact surface 253 and the fourth contact surface 255 in the direction 202 of the substrate thickness 227 or 411. As used herein, a minimum first polymer-based thickness 257 is defined as a minimum distance between the third contact surface 253 and the fourth contact surface 255 in the direction 202 of the substrate thickness 227 or 411. In further aspects, as shown in FIGS. 3-5, the maximum first polymer-based thickness 259 and the minimum first polymer-based thickness 257 can be substantially equal, for example, when the first polymer-based portion does not extend into the first recess 219 or 445. In further aspects, as shown in FIGS. 2 and 6, the minimum first polymer-based thickness 257 can be different from the maximum first polymer-based thickness 259, for example, when the first polymer-based layer extends into the first recess 219 or 445. In even further aspects, a difference between the maximum first polymer-based thickness 259 and the minimum first polymer-based thickness 257 can be about 1 μm or more, about 5 μm or more, about 10 μm or more, about 40 μm or less, about 20 μm or less, or about 10 μm or less. In even further aspects, an amount that the maximum first polymer-based thickness 259 is greater than the minimum first polymer-based thickness 257 can be in a range from about 1 μm to about 40 μm, from about 5 μm to about 40 μm, from about 5 μm to about 20 μm, from about 5 μm to about 10 μm, or any range or subrange therebetween. In aspects, the maximum first polymer-based thickness 259 can be about 5 μm or more, about 10 μm or more, about 20 μm or more, about 40 μm or more, about 500 μm or less, 200 μm or less, about 100 μm or less, about 80 μm or less, or about 60 μm or less. In further aspects, the maximum first polymer-based thickness 259 can be in a range from about 5 μm to about 500 μm, from about 5 μm to about 200 μm, from about 5 μm to about 100 μm, from about 10 μm to about 100 μm, from about 20 μm to about 100 μm, from about 20 μm to about 80 μm, from about 20 μm to about 60 μm, from about 40 μm to about 60 μm, or any range or subrange therebetween. Providing a first polymer-based portion can increase a puncture resistance and/or mechanical stability of the foldable apparatus.

In aspects, the first polymer-based portion 251 can comprise an elastic modulus (e.g., Young's modulus). In aspects, the elastic modulus of the first polymer-based portion 251 can be about 500 MPa or more, 1 GigaPascal (GPa) or more, about 2 GPa or more, about 5 GPa or more, about 20 GPa or less, about 10 GPa or less, or about 8 GPa or less. In aspects, the elastic modulus of the first polymer-based portion 251 can be in a range from about 500 MPa to about 20 GPa, from about 1 GPa to about 10 GPa, from about 2 GPa to about 10 GPa, from about 2 GPa to about 8 GPa, from about 5 GPa to about 8 GPa, or any range or subrange therebetween. In aspects, a Poisson's ratio of the first polymer-based portion 251 can be about 0.05 or more, about 0.10 or more, about 0.20 or more, about 0.25 or more, about 0.50 or less, about 0.40 or less, about 0.35 or less, or about 0.30 or less. In aspects, a Poisson's ratio of the first polymer-based portion 251 can be in a range from about 0.05 to about 0.50, from about 0.10 to about 0.50, from about 0.10 to about 0.40, from about 0.20 to about 0.40, from about 0.20 to about 0.35, from about 0.25 to about 0.35, from about 0.25 to about 0.30, or any range or subrange therebetween.

In aspects, the first polymer-based portion 251 can comprise polymers, blends, nanoparticle composites, and/or fiber composites of one or more of styrene-based polymers (e.g., polystyrene (PS), styrene acrylonitrile (SAN), styrene maleic anhydride (SMA)), phenylene-based polymer (e.g., polyphenylene sulfide (PPS)), polyvinylchloride (PVC), polysulfone (PSU), polyphthalamide (PPA), polyoxymethylene (POM), polylactide (PLA), polyimides (PI), polyhydroxybutyrate (PHB), polyglycolides (PGA), polyethyleneterephthalate (PET), and/or polycarbonate (PC). In aspects, the first polymer-based portion 251 can comprise a polymer-based material comprising a glass-transition (Tg) temperature within one or more of the ranges discussed above for the Tg of the first adhesive layer 261. In aspects, the first polymer-based portion 251 can comprise a coefficient of thermal expansion within one or more of the ranges discussed above for the CTE of the first adhesive layer 261.

In aspects, the first polymer-based portion 251 can comprise a strain at yield of about 3% or more, about 5% or more, about 10,000% or less, about 1,000% or less, about 100% or less, about 50% or less, about 20% or less, about 10% or less, or about 8% or less. In aspects, the strain at yield of the first polymer-based portion 251 can be in a range from about 3% to about 10,000%, from about 3% to about 1,000%, from about 3% to about 100%, from about 3% to about 50%, from about 3% to about 20%, from about 3% to about 10%, from about 5% to about 10%, from about 5% to about 8%, or any range or subrange therebetween. In aspects, the first polymer-based portion 251 can remain within an elastic deformation regime when the foldable apparatus achieves a parallel plate distance of 3 mm or less (discussed below). In aspects, the first polymer-based portion 251 can comprise a flexural rigidity of about 5×10⁻⁸ Pa m³ or more, about 10⁻⁷ Pa m³ or more, about 10⁻⁶ Pa m³ or more, about 10⁻³ Pa m³ or less, about 10⁻⁴ Pa m³ or less, or about 10⁻⁵ Pa m³ or less. In aspects, the first polymer-based portion 251 can comprise a flexural rigidity in a range from about 5×10⁻⁸ Pa m³ to about 10⁻³ Pa m³, from about 5×10⁻⁸ Pa m³ to about 10⁻⁴ Pa m³, from about 10⁻⁷ Pa m³ to about 10⁻⁴ Pa m³, from about 10⁻⁷ Pa m³ to about 10⁻⁵ Pa m³, from about 10⁻⁶ Pa m³ to about 10⁻⁵ Pa m³, or any range or subrange therebetween.

In aspects, as shown in FIGS. 4-5, a second adhesive layer 461 can be disposed in the second recess 447. In further aspects, as shown, the second adhesive layer 461 can be completely within the second recess 447. In aspects, as shown in FIGS. 4-5, the second adhesive layer 461 can comprise a fifth contact surface 463 and a sixth contact surface 465 opposite the fifth contact surface 463. In further aspects, the sixth contact surface 465 can face and/or contact the second central surface area 443. As used herein, a maximum second adhesive thickness 469 is defined as a maximum distance between the fifth contact surface 463 and the sixth contact surface 465 in the direction 202 of the substrate thickness 411. As used herein, a minimum second adhesive thickness 467 is defined as a minimum distance between the fifth contact surface 463 and the sixth contact surface 465 in the direction 202 of the substrate thickness 411. In further aspects, as shown in FIGS. 4-5, the maximum second adhesive thickness 469 and the minimum second adhesive thickness 467 can be substantially equal, for example, when the second adhesive layer 461 is completely within the second recess 447 and/or the second adhesive layer 461 does not extend beyond the central portion 481. In further aspects, although not shown, the minimum second adhesive thickness can be different from the maximum second adhesive thickness, for example, when the second adhesive layer extends beyond the central portion, and/or a difference between the maximum second adhesive thickness and the minimum second adhesive thickness can be substantially equal to the second distance 437 that the second central surface area 443 is recessed from the second major surface 405. In even further aspects, when the maximum second adhesive thickness is different than the minimum second adhesive thickness, the minimum second adhesive thickness can be within one or more of the ranges discussed above for the minimum first adhesive thickness. In further aspects, the maximum second adhesive thickness 469 can be within one or more of the ranges discussed above for the maximum first adhesive thickness 269. Providing a second adhesive thickness of about 5 μm or more can be sufficient to provide a neutral plane within the second adhesive portion, which can provide further benefits discussed below.

In aspects, an elastic modulus of the second adhesive layer 461 can be within one or more of the ranges discussed above for the elastic modulus of the first adhesive layer 261. In aspects, a Poisson's ratio of the second adhesive layer 461 can be within one or more of the ranges discussed above for the Poisson's ratio of the first adhesive layer 261. In aspects, a flexural rigidity of the second adhesive layer 461 can be within one or more of the ranges discussed above for the flexural rigidity of the first adhesive layer 261. In aspects, the second adhesive layer 461 can comprise one or more of the materials discussed above for the first adhesive layer 261. In aspects, the second adhesive layer 461 can comprise a strain at yield and/or remain within an elastic deformation regime within the corresponding ranges discussed above for the first adhesive layer 261.

In aspects, as shown in FIG. 4, the maximum second adhesive thickness 469 can be less than the second distance 437 that the second central surface area 443 is recessed from the second major surface 405. In even further aspects, the maximum second adhesive thickness 469 can be less than the second distance 437 by about 10 μm or more, about 15 μm or more, or about 20 μm or more. In aspects, as shown in FIG. 5, the maximum second adhesive thickness 469 can be substantially equal to the second distance 437 that the second central surface area 443 is recessed from the second major surface 405. In further aspects, as shown, the fifth contact surface 463 can extend along a common plane (e.g., second plane 404b) with the second major surface 405. In aspects, although not shown, the maximum second adhesive thickness 469 can be greater than the second distance 437 that the second central surface area 443 is recessed from the second major surface 405. In further aspects, the maximum second adhesive thickness 469 can be greater than the second distance 437 by about 1 μm or more, about 5 μm or more, about 10 μm or more, about 40 μm or less, about 20 μm or less, or about 10 μm or less.

In aspects, as shown in FIG. 5, the maximum first adhesive thickness 269 can be substantially equal to the maximum second adhesive thickness 469. In aspects, as shown in FIG. 4, the maximum first adhesive thickness 269 can be greater than the maximum second adhesive thickness 469, for example, by about 1 μm or more, about 5 μm or more, or about 10 μm or more. In aspects, although not shown, the maximum second adhesive thickness 469 can be greater than the maximum first adhesive thickness 269, for example, by about 1 μm or more, about 5 μm or more, or about 10 μm or more.

In aspects, as shown in FIGS. 4-5, a second polymer-based portion 451 can be disposed on the second adhesive layer 461. In aspects, as shown in FIG. 4, the second polymer-based portion 451 can be at least partially positioned in the second recess 447. In further aspects, as shown, the second polymer-based portion 451 can be entirely positioned in the second recess 447. In aspects, as shown in FIG. 5, the second polymer-based portion 451 may not be positioned in the second recess 447. In aspects, as shown in FIGS. 4-5, the second adhesive layer 461 can be positioned between the second polymer-based portion 451 and the second central surface area 443. In further aspects, although not shown, the second adhesive layer can be positioned between the second polymer-based portion and the first portion 421 (e.g., second surface area 425) and/or between the second polymer-based portion and the second portion 431 (e.g., fourth surface area 435).

In aspects, as shown in FIGS. 4-5, the second polymer-based portion 451 can comprise a seventh contact surface 453 and an eighth contact surface 455 opposite the seventh contact surface 453. In further aspects, as shown, the eighth contact surface 455 of the second polymer-based portion 451 can face and/or contact the fifth contact surface 463 of the second adhesive layer 461, and the fifth contact surface 463 of the second adhesive layer 461 can face and/or contact the eighth contact surface 455 of the second polymer-based portion 451. In further aspects, as shown, the eighth contact surface 455 can face the second central surface area 443, the second surface area 425, and/or the fourth surface area 435. In even further aspects, as shown in FIG. 5, the eighth contact surface 455 can contact the second surface area 425 and/or the fourth surface area 435. In aspects, as shown in FIG. 5, the eighth contact surface 455 can extend along the second plane 404b that the second major surface. Providing the second adhesive layer positioned between the first central surface area and the second polymer-based portion can provide a neutral plane within the first adhesive portion, which can provide further benefits discussed below.

As used herein, a maximum second polymer-based thickness 459 is defined as a maximum distance between the seventh contact surface 453 and the eighth contact surface 455 in the direction 202 of the substrate thickness 411. As used herein, a minimum second polymer-based thickness 457 is defined as a minimum distance between the seventh contact surface 453 and the eighth contact surface 455 in the direction 202 of the substrate thickness 411. In aspects, as shown in FIG. 5, the maximum second polymer-based thickness 459 and the minimum second polymer-based thickness 457 can be substantially equal, for example, when the second polymer-based portion does not extend into the second recess 447. In aspects, although not shown, the minimum second polymer-based thickness 457 can be different from the maximum second polymer-based thickness 459, for example, when the second polymer-based layer extends into the second recess 447. In further aspects, a difference between the maximum second polymer-based thickness 459 and the minimum second polymer-based thickness 457 can be about 1 μm or more, about 5 μm or more, about 10 μm or more, about 40 μm or less, about 20 μm or less, or about 10 μm or less. In aspects, the maximum second polymer-based thickness 459 can be within one or more of the ranges discussed above for the maximum first polymer-based thickness 259.

In aspects, an elastic modulus of the second polymer-based portion 451 can be within one or more of the ranges discussed above for the elastic modulus of the first polymer-based portion 251. In aspects, a Poisson's ratio of the second polymer-based portion 451 can be within one or more of the ranges discussed above for the Poisson's ratio of the first polymer-based portion 251. In aspects, a flexural rigidity of the second polymer-based portion 451 can be within one or more of the ranges discussed above for the flexural rigidity of the first polymer-based portion 251. In aspects, the second polymer-based portion 451 can comprise one or more of the materials discussed above for the first polymer-based portion 251. In aspects, the second polymer-based portion 451 can comprise one or more of the materials discussed below for the coating 471. In aspects, the second polymer-based portion 451 can comprise a pencil hardness within one or more of the ranges discussed below for the pencil hardness of the coating 471. In aspects, the second polymer-based portion 451 can comprise a strain at yield and/or remain within an elastic deformation regime within the corresponding ranges discussed above for the first polymer-based portion 251.

In aspects, a ratio of the elastic modulus of the first polymer-based portion 251 to the elastic modulus of the first adhesive layer 261 can be about 500 or more, about 750 or more, about 1,000 or more, about 5,000 or more, about 8,000 or more, about 10,000 or more, about 15,000 or more, about 30,000 or more, about 60,000 or more, about 500,000 or less, about 400,000 or less, about 300,000 or less, about 150,000 or less, or about 100,000 or less. In aspects, a ratio of the elastic modulus the first polymer-based portion 251 to the elastic modulus of the first adhesive layer 261 can be in a range from about 500 to about 500,000, from about 500 to about 400,000, from about 750 to about 400,000, from about 1,000 to about 400,000, from about 1,000 to about 300,000, from about 3,000 to about 300,000, from about 5,000 to about 300,000, from about 8,000 to about 300,000, from about 8,000 to about 150,000, from about 10,000 to about 150,000, from about 10,000 to about 100,000, from about 15,000 to about 100,000, from about 30,000 to about 100,000, from about 60,000 to about 100,000, or any range or subrange therebetween. In aspects, a ratio of the elastic modulus of the second polymer-based portion 451 to the elastic modulus of the second adhesive layer 461 can be within one or more of the ranges discussed above in this paragraph. In aspects, a ratio of the flexural rigidity of the first polymer-based portion 251 to the flexural rigidity of the first adhesive layer 261 can be about 500 or more, 1,000 or more, about 4,000 or more, about 8,000 or more, about 12,000 or more, about 16,000 or more, about 20,000 or more, about 500,000, about 250,000 or less, about 100,000 or less, about 40,000 or less, about 30,000 or less, or about 25,000 or less. In aspects, a ratio of the flexural rigidity of the first polymer-based portion 251 to the flexural rigidity of the first adhesive layer 261 can be in a range from about 500 to about 500,000, from about 1,000 to about 500,000, from about 1,000 to about 250,000, from about 1,000 to about 100,000, from about 4,000 to about 100,000, from about 4,000 to about 40,000, from about 8,000 to about 40,000, from about 12,000 to about 40,000, from about 12,000 to about 30,000, from about 16,000 to about 30,000, from about 20,000 to about 30,000, or any range or subrange therebetween. In aspects, a ratio of the flexural rigidity of the second polymer-based portion 451 to the flexural rigidity of the second adhesive layer 461 can be within one or more of the ranges discussed above for the ratio of the flexural rigidity of the first polymer-based portion 251 to the flexural rigidity of the first adhesive layer 261. Providing the first adhesive layer comprising a much lower (e.g., from about 500 times to about 500,000 times, from about 10,000 times to about 100,000 times) elastic modulus and/or flexural rigidity than the first polymer-based portion can reduce bend-induced stresses on the first polymer-based portion or the foldable substrate. Reducing bend-induced stresses can reduce (e.g., decreases, eliminate) bend-induced mechanical instabilities of the foldable apparatus. Also, reducing bend-induced stresses can reduce fatigue of the foldable apparatus while increasing the reliability and/or durability of the foldable apparatus.

In aspects, as shown in FIGS. 2, 4, and 6, the foldable apparatus 101, 401, or 601 can comprise a coating 471 disposed on the second major surface 205 or 405 of the foldable substrate 201 or 407. In further aspects, as shown, the coating 471 can comprise a fifth surface area 473 and a sixth surface area 475 opposite the fifth surface area 473. In further aspects, as shown, the coating 471 (e.g., sixth surface area 475) can contact the second major surface 205 or 405 (e.g., second surface area 225 or 425, fourth surface area 235 or 435). In aspects, as shown in FIG. 4, the coating can be disposed on the second polymer-based portion 451 and/or the second adhesive layer 461. In aspects, the coating 471 can comprise a pencil hardness of about 5H or more, about 6H or more, about 7H or more, about 8H or more, or about 9H or more. In aspects, the coating can comprise an elastic modulus within one or more of the ranges discussed above for the elastic modulus of the first polymer-based portion 251.

As used herein, a maximum coating thickness 479 is defined as a maximum distance between the fifth surface area 473 and the sixth surface area 475 in the direction 202 of the substrate thickness 227 or 411. As used herein, a minimum coating thickness 477 is defined as a minimum distance between the fifth surface area 473 and the sixth surface area 475 in the direction 202 of the substrate thickness 227 or 411. In aspects, as shown in FIGS. 2 and 4, the maximum coating thickness 479 and the minimum coating thickness 477 can be substantially equal, for example if the coating 471 does not extend into the second recess 447, if present. In aspects, as shown in FIG. 6, the maximum coating thickness 479 can be greater than minimum coating thickness 477, for example if the coating 471 extends into the second recess 447. In further aspects, a difference between the maximum coating thickness 479 and the minimum coating thickness 477 can be within one or more of the ranges discussed above for the second distance 437. In aspects, the maximum coating thickness 479 can be about 1 μm or more, about 10 μm or more, about 20 μm or more, about 30 μm or more, about 40 μm or more, about 50 μm or more, about 60 μm or more, about 70 μm or more, about 150 μm or less, about 140 μm or less, about 130 μm or less, about 120 μm or less, about 110 μm or less, about 100 μm or less, about 90 μm or less, or about 80 μm or less. In aspects, the maximum coating thickness 479 can be in a range from about 1 μm to about 150 μm, from about 10 μm to about 140 μm, from about 20 μm to about 130 μm, from about 30 μm to about 120 μm, from about 40 μm to about 110 μm, from about 50 μm to about 100 μm, from about 60 μm to about 90 μm, from about 70 μm to about 80 μm, or any range or subrange therebetween.

In aspects, the coating 471 can comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of about 500 μm or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example, an amine, for example, an alkyl aminosilane with oxymethyl groups pendant on the silicon atom. In such aspects, the oleophobic coating may comprise the same material as the easy-to-clean coating. In aspects, a diamond-like coating comprising carbon and may be created by applying a high voltage potential in the presence of a hydrocarbon plasma. Further, the coating may be a hard-coat material that is disposed on and/or bonded to the foldable substrate. Suitable materials for an optically transparent polymeric hard-coat layer include but are not limited to a cured acrylate resin material, an inorganic-organic hybrid polymeric material, an aliphatic or aromatic hexafunctional urethane acrylate, a siloxane based hybrid material, and a nanocomposite material, for example, an epoxy and urethane material with nanosilicate. In aspects, an optically transparent polymeric hard-coat layer may consist essentially of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulate dispersed within an organic matrix. More specifically, suitable materials for an optically transparent polymeric (OTP) hard-coat layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP hard-coat layer may consist essentially of an organic polymer material, an inorganic-organic hybrid polymeric material, or aliphatic or aromatic hexafunctional urethane acrylate. In aspects, an OTP hard-coat layer may consist of a polyimide, an organic polymer material, an inorganic-organic hybrid polymeric material, or aliphatic or aromatic hexafunctional urethane acrylate. In aspects, an OTP hard-coat layer may include a nanocomposite material. In aspects, an OTP hard-coat layer may include a nano-silicate at least one of epoxy and urethane materials. Suitable compositions for such an OTP hard-coat layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP hard-coat layer may comprise an organic polymer material manufactured by Gunze Limited and having a hardness of 9H, for example, Gunze's “Highly Durable Transparent Film.” In aspects, the inorganic-organic hybrid polymeric material may include polymerized monomers comprising an inorganic silicon-based group, for example, a silsesquioxane polymer. A silsesquioxane polymer may be, for example, an alky-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP hard-coat layer may comprise a silsesquioxane polymer combined with an organic matrix, for example, SILPLUS manufactured by Nippon Steel Chemical Co., Ltd. In aspects, an OTP hard-coat layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by Ciba Specialty Chemicals Corporation) with a hardness of 8H or more. In aspects, an OTP hard-coat layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. In aspects, an OTP hard-coat layer may be an inorganic-organic hybrid polymeric material or an organic polymer material. In aspects, an OTP hard-coat layer may be an aliphatic or aromatic hexafunctional urethane acrylate material.

Throughout the disclosure, “optically transparent” means an average transmittance of 70% or more in the wavelength range of 400 nm to 700 nm through a 1.0 mm thick piece of a material. In aspects, an optically transparent material may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements. In aspects, the foldable apparatus 101, 301, 401, 501, or 601 can be optically transparent. In aspects, the foldable substrate 201 or 407 can be optically transparent. In aspects, the first adhesive layer 261 and/or the second adhesive layer 461 can be optically transparent. In aspects, the first polymer-based portion 251, the second polymer-based portion 451, and/or the coating 471 can be optically transparent.

Throughout the disclosure, an index of refraction may be a function of a wavelength of light passing through a material. Throughout the disclosure, for light of a first wavelength, an index of refraction of a material is defined as the ratio between the speed of light in a vacuum and the speed of light in the corresponding material. Without wishing to be bound by theory, an index of refraction of a material can be determined using a ratio of a sine of a first angle to a sine of a second angle, where light of the first wavelength is incident from air on a surface of the material at the first angle and refracts at the surface of the material to propagate light within the material at a second angle. The first angle and the second angle are both measured relative to a normal of a surface of the material. As used herein, the refractive index is measured in accordance with ASTM E1967-19, where the first wavelength comprises 589 nm. In aspects, a first index of refraction of the foldable substrate 201 or 407 can be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, a first index of refraction of the foldable substrate 201 or 407 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween.

In aspects, the first adhesive layer 261 can comprise a second index of refraction. In further aspects, the second index of refraction of the first adhesive layer 261 can be within one or more of the ranges discussed above for the first index of refraction. In further aspects, a magnitude of a difference between the first index of refraction of the foldable substrate 201 or 407 and the second index of refraction of the first adhesive layer 261 can be about 0.1 or less, about 0.07 or less, about 0.05 or less, about 0.03 or less, about 0.001 or more, about 0.01 or more, or about 0.02 or more. In further aspects, the magnitude of a difference is in a range from about 0.001 to about 0.1, from about 0.01 to about 0.07, from about 0.02 to about 0.05, from about 0.01 to about 0.02, or any range or subrange therebetween. In aspects, the second index of refraction may be greater than or less than the first index of refraction. In aspects, the second adhesive layer 461, if present, can comprise an index of refraction substantially equal to the second index of refraction of the first adhesive layer 261. In aspects, a magnitude of a difference between the first index of refraction of the foldable substrate 201 or 407 and the index of refraction of the second adhesive layer 461, if present, can be within one or more of the ranges discussed above for the magnitude of a difference between the first index of refraction and the second index of refraction. Providing a second index of refraction that substantially matches a first index of refraction of an adjacent index of refraction can reduce (e.g., mitigate, avoid) optical distortions that may otherwise occur with a mismatched index of refraction.

In aspects, the first polymer-based portion 251 can comprise a third index of refraction. In further aspects, the third index of refraction of the first polymer-based portion 251 can be within one or more of the ranges discussed above for the first index of refraction. In further aspects, a magnitude of a difference between the first index of refraction of the foldable substrate 201 or 407 and the third index of refraction of the first polymer-based portion 251 can be within one or more of the ranges discussed above for the magnitude of a difference between the first index of refraction and the second index of refraction. In further aspects, a magnitude of a difference between the second index of refraction of the first adhesive layer 261 and the third index of refraction of the first polymer-based portion 251 can be within one or more of the ranges discussed above for the magnitude of a difference between the first index of refraction and the second index of refraction. In aspects, the second polymer-based portion 451, if present, can comprise an index of refraction substantially equal to the third index of refraction of the first polymer-based portion 251. In aspects, a magnitude of a difference between the first index of refraction of the foldable substrate 201 or 407 and the index of refraction of the second polymer-based portion 451, if present, can be within one or more of the ranges discussed above for the magnitude of a difference between the first index of refraction and the second index of refraction. Providing a third index of refraction that substantially matches a first index of refraction of an adjacent index of refraction can reduce (e.g., mitigate, avoid) optical distortions that may otherwise occur with a mismatched index of refraction.

In aspects, as shown in FIGS. 2 and 4, the foldable apparatus 101 and 401 can comprise the release liner 271 although other substrates (e.g., a glass-based substrate) may be used in further aspects rather than the illustrated release liner 271. In further aspects, as shown, the release liner 271, or other substrates, can be disposed on the first adhesive layer 261 and/or the first polymer-based portion 251. In even further aspects, as shown, the release liner 271, or other substrates, can directly contact the third contact surface 253 of the first polymer-based portion 251. As shown, the release liner 271, or other substrates, can be disposed on the first polymer-based portion 251 by attaching the third contact surface 253 of the first polymer-based portion 251 to the fourth major surface 275 of the release liner 271, or other substrates. In aspects, although not shown, an additional adhesive layer can be positioned between the first polymer-based portion and the release liner. In aspects, as shown, a third major surface 273 of the release liner 271, or other substrates, can comprise a planar surface. In aspects, as shown, the fourth major surface 275 of the release liner 271, or other substrates, can comprise a planar surface. A substrate comprising the release liner 271 can comprise a paper and/or a polymer. Exemplary aspects of paper comprise kraft paper, machine-finished paper, poly-coated paper (e.g., polymer coated, glassine paper, siliconized paper), or clay-coated paper. Exemplary aspects of polymers comprise polyesters (e.g., polyethylene terephthalate (PET)) and polyolefins (e.g., low-density polyethylene (LDPE), high-density polyethylene (HDPE), polypropylene (PP)).

In aspects, as shown in FIGS. 3 and 5-6, the foldable apparatus 301, 501, and 601 can comprise the display device 307. In further aspects, as shown in FIGS. 3 and 5-6, the display device 307 can be disposed on the first adhesive layer 261 and/or the first polymer-based portion 251. In even further aspects, as shown, the display device 307 can contact the third contact surface 253 of the first polymer-based portion 251. In aspects, producing the foldable apparatus 301, 501, or 601 may be achieved by removing the release liner 271 of the foldable apparatus 101 or 401 of FIG. 2 or 4 and attaching the display device 307 to the third contact surface 253 of the first polymer-based portion 251. Alternatively, the foldable apparatus 301, 501, or 601 may be produced without the extra step of removing a release liner 271 before attaching the display device 307 to the third contact surface 253 of the first polymer-based portion 251, for example, when a release liner 271 is not applied to the third contact surface 253 of the first polymer-based portion 251. The display device 307 can comprise a third major surface 303 and a fourth major surface 305 opposite the third major surface 303. As shown in FIGS. 3 and 5-6, the display device 307 can be disposed on the first polymer-based portion 251 by attaching the third contact surface 253 of the first polymer-based portion 251 to the third major surface 303 of the display device 307. In aspects, although not shown, an additional adhesive layer can be positioned between the first polymer-based portion and the display device. In aspects, as shown in FIGS. 3 and 5-6, the third major surface 303 of the display device 307 can comprise a planar surface. In aspects, as shown, the fourth major surface 305 of the display device 307 can comprise a planar surface. The display device 307 can comprise a liquid crystal display (LCD), an electrophoretic display (EPD), an organic light-emitting diode (OLED) display, or a plasma display panel (PDP). In aspects, the display device 307 can be part of a portable electronic device, for example, a consumer electronic product, a smartphone, a tablet, a wearable device, or a laptop.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent the front surface of the housing. The consumer electronic product can comprise a cover substrate disposed on the display. In aspects, at least one of a portion of the housing or the cover substrate comprises the foldable apparatus discussed throughout the disclosure.

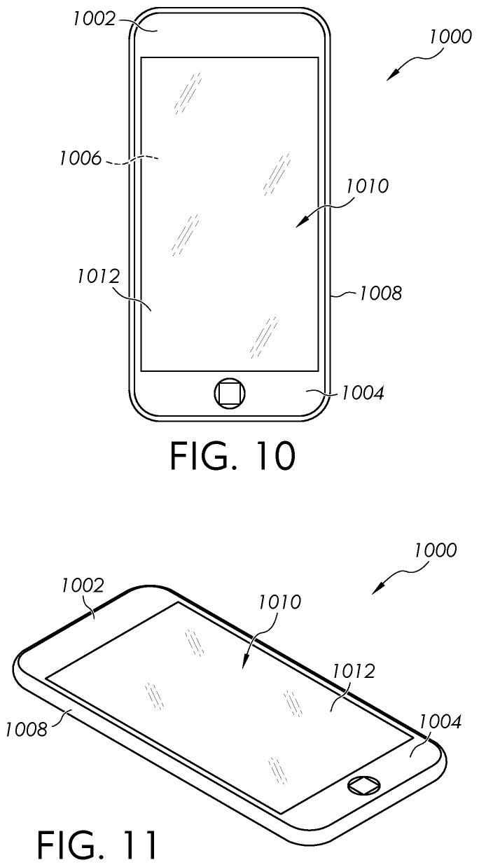

The foldable apparatus disclosed herein may be incorporated into another article, for example, an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc.), appliance articles, or any article that may benefit from some transparency, scratch resistance, abrasion resistance or a combination thereof. An exemplary article incorporating any of the foldable apparatus disclosed herein is shown in FIGS. 10 and 11. Specifically, FIGS. 10 and 11 show a consumer electronic device 1000 including a housing 1002 having front 1004, back 1006, and side surfaces 1008; electrical components (not shown) that are at least partially inside or entirely within the housing and including at least a controller, a memory, and a display 1010 at or adjacent to the front surface of the housing; and a cover substrate 1012 at or over the front surface of the housing such that it is over the display. In aspects, at least one of the cover substrate 1012 or a portion of housing 1002 may include any of the foldable apparatus disclosed herein.

Throughout the disclosure, with reference to FIG. 1, a width 103 of the foldable apparatus is considered the dimension of the foldable apparatus taken between opposed edges of the foldable apparatus in a direction 104 of a fold axis 102 of the foldable apparatus. Furthermore, throughout the disclosure, the length 105 of the foldable apparatus is considered the dimension of the foldable apparatus taken between opposed edges of the foldable apparatus in a direction 106 perpendicular to the fold axis 102 of the foldable apparatus. In aspects, as shown in FIGS. 1-6, the foldable apparatus can comprise a fold plane 109 that includes the fold axis 102 extending along the direction 202 of the substrate thickness 227 or 411 when the foldable apparatus is in the flat configuration. In aspects, the fold plane 109 may comprise a central axis 107 of the foldable apparatus, which can be positioned at the second major surface 205 as shown in FIG. 2. In aspects, the foldable apparatus can be folded in a direction 111 (e.g., see FIG. 1) about the fold axis 102 extending in the direction 104 of the width 103 to form a folded configuration (e.g., see FIGS. 7-9). In aspects, as shown in FIGS. 1-6, the foldable apparatus 101, 301, 401, 501, and 601 may be substantially symmetric about a plane (e.g., see fold plane 109 in FIG. 1). As shown, the foldable apparatus may include a single fold axis to allow the laminate to comprise a bifold wherein, for example, the foldable apparatus may be folded in half. In further aspects, the foldable apparatus may include two or more fold axes. For example, providing two fold axes can allow the foldable apparatus to comprise a trifold.

FIGS. 7-9 schematically illustrate example aspects of the foldable apparatus 701 or 901 in accordance with aspects of the disclosure in the folded configuration. In aspects, as shown in FIG. 8, the foldable apparatus 701 can be folded such that the second major surface 205 is on the inside of the folded foldable apparatus 701 while the first major surface 203 faces the outside of the folded foldable apparatus 701. In further aspects, the folded foldable apparatus 701 can correspond to the foldable apparatus 301 shown in FIG. 3 that has been modified for the Parallel Plate Test and folded to achieve the folded configuration shown in FIG. 8. In even further aspects, the display device 307 shown in FIG. 3 would be on the outside of the folded foldable apparatus 701 (e.g., if the foldable apparatus was not modified for the Parallel Plate Test by replacing the display device 307 with the PET sheet 807) such that a user would view the foldable apparatus and, thus, would be positioned on the side of the second major surface 205 and viewing from the side of the second major surface 205. In aspects, as shown in FIG. 9, the foldable apparatus 901 can be folded such that the first major surface 403 faces the inside of the folded foldable apparatus 901 while the second major surface 405 faces the outside of the folded foldable apparatus 901. In further aspects, the folded foldable apparatus 901 can correspond to the foldable apparatus 501 shown in FIG. 5. In further aspects, the display device 307 is on the inside of the folded foldable apparatus 901 such that a user would view the display device through the foldable apparatus and, thus, would be positioned on the side of the second major surface 405 and viewing from the side of the second major surface 405. In aspects, as shown in FIG. 7, the foldable apparatus 401, 501, and 601 can be folded such that a first outer surface 409 of the foldable apparatus 401, 501, and 601 can be on the inside of the fold. In further aspects, as shown in FIGS. 4-6, a second outer surface 419 can be opposite the first outer surface 409 such that if the foldable apparatus 401, 501, and 601 is folded as shown in FIG. 7, the second outer surface 419 will be on the outside of the fold.

As used herein, “foldable” includes complete folding, partial folding, bending, flexing, or multiple capabilities. As used herein, the terms “fail,” “failure” and the like refer to breakage, destruction, delamination, or crack propagation. A foldable substrate achieves a parallel plate distance of “X,” or has a parallel plate distance of “X,” or comprises a parallel plate distance of “X” if it resists failure when the substrate is held at a parallel plate distance of “X” for 24 hours at about 60° C. and about 90% relative humidity.

As used herein, the “parallel plate distance” of a foldable apparatus is measured using the Parallel Plate Test with the following test configuration and process using a parallel plate apparatus 801 (see FIG. 8) that comprises a pair of parallel rigid stainless-steel plates 803, 805 comprising a first rigid stainless-steel plate 803 and a second rigid stainless-steel plate 805. When measuring the “parallel plate distance” with the Parallel Plate Test for the foldable apparatus 301, as shown in FIG. 8, the foldable apparatus 301 of FIG. 3 is modified to form foldable apparatus 701 by replacing the material beyond the third contact surface 253 of the first polymer-based portion 251, namely, replacing the display device 307, with a 100 μm thick sheet of poly(ethylene terephthalate) (PET) 807. When measuring the “parallel plate distance” for the foldable apparatus 401, the foldable apparatus 401 is modified by replacing the material beyond the third contact surface 253 of the first polymer-based portion 251, namely replacing the release liner 271 with a 100 μm thick sheet of PET. As shown in FIG. 8, the modified foldable apparatus 701 is placed between the pair of parallel rigid stainless-steel plates 803 and 805 such that the PET sheet 807 is on the outside of the bend. The distance between the parallel plates is reduced at a rate of 50 μm/second until the parallel plate distance 811 is equal to the “parallel plate distance” to be tested. Then, the parallel plates are held at the “parallel plate distance” to be tested for 24 hours at about 60° C. and about 90% relative humidity. As used herein, the “minimum parallel plate distance” is the smallest parallel plate distance that the foldable apparatus can withstand without failure under the conditions and configuration described above.

In aspects, the foldable apparatus 101, 301, 401, 501, 601, 701, or 901 can achieve a parallel plate distance of 100 mm or less, 50 mm or less, 20 mm or less, or 10 mm or less. In further aspects, the foldable apparatus 101, 301, 401, 501, 601, 701, or 901 can achieve a parallel plate distance of 10 millimeters (mm), or 7 mm, or 5 mm, or 1 mm. In aspects, the foldable apparatus 101, 301, 401, 501, 601, 701, or 901 can comprise a minimum parallel plate distance of about 10 mm or less, about 7 mm or less, about 5 mm or less, about 1 mm or more, about 2 mm or more, or about 5 mm or more. In aspects, the foldable apparatus 101, 301, 401, 501, 601, 701, or 901 can comprise a parallel plate distance and/or a minimum parallel plate distance in a range from about 1 mm to about 10 mm, from about 1 mm to about 7 mm, from about 2 mm to about 7 mm, from about 2 mm to about 5 mm, or any range or subrange therebetween.

In aspects, the width 252 or 449 of the central portion 281 or 481 of the foldable substrate 201 or 407 can extend from the first portion 221 or 421 to the second portion 231 or 431. In aspects, the width 252 or 449 of the central portion 281 or 481 of the foldable substrate 201 or 407 defined between the first portion 221 or 421 and the second portion 231 or 431 in the direction 106 of the length 105 can be about 2.2 times or more, about 2.8 time or more, about 3 times or more, about 4 times or more, about 6 times or less, about 5 times or less, or about 4 times or less the minimum parallel plate distance. In aspects, the width 252 or 449 of the central portion 281 or 481 as a multiple of the minimum parallel plate distance can be in a range from about 2.2 times to about 6 times, from about 2.8 times to about 6 times, from about 2.8 times to about 5 times, from about 2.8 times to about 4 times, from about 3 times to about 4 times, from about 4 times to about 5 times, or any range or subrange therebetween. Without wishing to be bound by theory, the length of a bent portion in an elliptical configuration between parallel plates can be about 2.2 times the parallel plate distance 811.

A minimum force may be used to achieve a predetermined parallel plate distance with the foldable apparatus. The parallel plate apparatus 801 of FIG. 8, described above, is used to measure the “bend force” of a foldable apparatus (i.e., “apparatus bend force”) or a portion of a foldable apparatus of the aspects of the disclosure, and the foldable apparatus is modified as described above for the Parallel Plate Test (i.e., replacing any components beyond the third contact surface 253 of the first polymer-based portion 251 with the PET sheet 807). The force to go from a flat configuration (e.g., see FIG. 3) to a bent (e.g., folded) configuration (e.g., see FIG. 8) comprising the predetermined parallel plate distance is measured. In aspects, an apparatus bend force comprising the minimum force to bend the foldable apparatus from a flat configuration to a parallel plate distance of 3 mm can be about 0.01 Newtons per millimeter width of the foldable apparatus (N/mm) or less, about 0.008 N/mm or less, about 0.006 N/mm or less, about 0.0001 N/mm or more, about 0.001 N/mm or more, or about 0.002 N/mm or more. In aspects, an apparatus bend force comprising the minimum force to bend the foldable apparatus from a flat configuration to a parallel plate distance of 3 mm can be in a range from about 0.0001 N/mm to about 0.01 N/mm, from about 0.001 N/mm to about 0.01 N/mm, from about 0.001 N/mm to about 0.008 N/mm, from about 0.002 N/mm to about 0.008 N/mm, from about 0.002 N/mm to about 0.006 N/mm, or any range or subrange therebetween.

As used herein, a “total bend force” is a sum of a force to bend each component individually. For example, with reference to FIG. 3, the total bend force would be the sum of bend forces for (1) the foldable substrate 201, (2) the first adhesive layer 261, (3) the first polymer-based portion, and (4) the PET sheet 807 (since the foldable apparatus is modified as described above for the Parallel Plate Test). In aspects, an apparatus bend force, as a multiple of a total bend force comprising a force to bend each component individually, can be about 0.5 times or more, about 0.6 times or more, about 0.75 times or more about 0.8 or more, about 1 or less, about 0.95 or less, about 0.9 or less, or about 0.85 or less. In aspects, an apparatus bend force, as a multiple of a total bend force comprising a force to bend each component individually, can be in a range from about 0.5 times to about 1 times, from about 0.6 times to about 1 times, from about 0.6 times to about 0.95 times, from about 0.75 times to about 0.95 times, from about 0.75 times to about 0.9 times, from about 0.8 times to about 0.9 times, from about 0.8 to about 0.85 times, or any range or subrange therebetween. Providing a foldable apparatus with an apparatus bend force near (e.g., within a factor of 2, from about 0.5 times to about 1 times) a total bend force from bending each first portion individually can enable low user-applied forces to fold the foldable apparatus. Also, this can reflect a decreased coupling of bend-induced stresses between adjacent pairs of first portions.

Throughout the disclosure, a strain of a portion of the foldable apparatus during a Parallel Plate Test is measured using digital image correlation methods. Digital image correlation methods use information visually recorded during the Parallel Plate Test to track changes to (e.g., deformation of) the foldable apparatus and/or components thereof, which are used to calculate displacements and therefore strains of the foldable apparatus and/or components thereof. Further, using the elastic modulus of a component, bending stress on a component (e.g., at a surface of the component) can be calculated. In aspects, an absolute value of a strain of the first polymer-based portion 251 at a location where the fold axis 102 impinges the third contact surface 253 when the foldable apparatus achieves a parallel plate distance of 3 mm can be about 4% or less, about 3.5% or less, about 3% or less, about 1% or more, about 2% or more, or about 2.5% or more. In aspects, an absolute value of a strain of the first polymer-based portion 251 at a location where the fold axis 102 impinges the third contact surface 253 when the foldable apparatus achieves a parallel plate distance of 3 mm can in a range from about 1% to about 4%, from about 2% to about 3.5%, from about 2.5% to about 3%, or any range or subrange therebetween. In aspects, an absolute value of a bending stress of the central portion 281 or 481 at the first central surface area 211 or 441 when the foldable apparatus achieves a parallel plate distance of about 3 mm can be about 900 MPa or less, about 890 MPa or less, about 880 MPa or less, about 700 MPa or more, about 800 MPa or more, or about 850 MPa or more. In aspects, an absolute value of a bending stress of the central portion 281 or 481 at the first central surface area 211 or 441 when the foldable apparatus achieves a parallel plate distance of about 3 mm can be in a range from about 700 MPa to about 900 MPa, from about 800 MPa to about 890 MPa, from about 850 MPa to about 880 MPa, or any range or subrange therebetween. Providing a low (e.g., 4% or less) strain of the first polymer-based portion when the foldable apparatus achieves a parallel plate distance of 3 mm can reduce requirements for the first polymer-based portion, which can reduce failure of the foldable apparatus, and/or enable the use of a wider range of materials for the polymer-based portion since the strain requirements have been eased. Providing a low (e.g., 900 MPa or less) bending stress on the central portion of the foldable apparatus when the foldable apparatus achieves a parallel plate distance of 3 mm can decrease a bend force and/or reduce failure of the foldable apparatus.

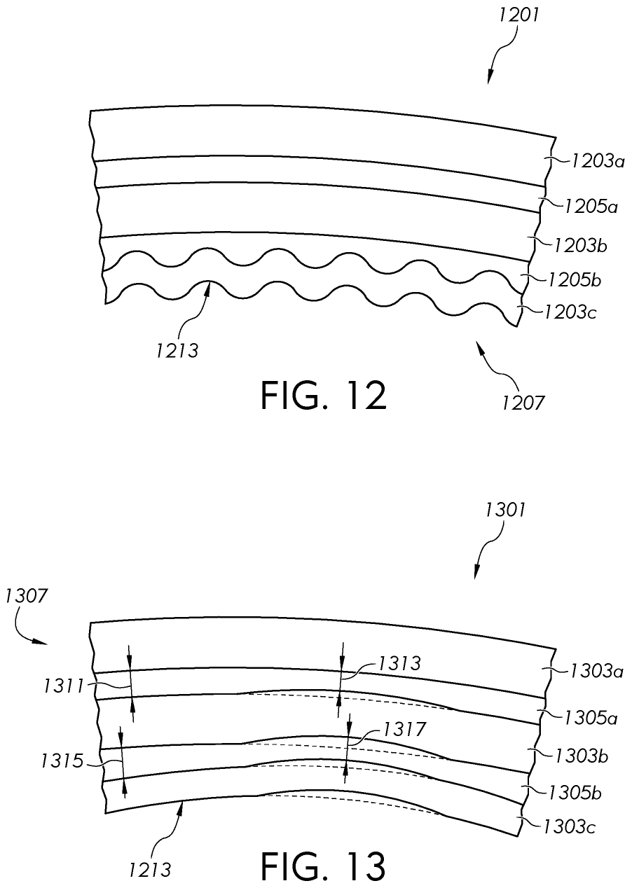

Aspects of the disclosure (e.g., providing a first adhesive layer within the first recess, providing a first adhesive layer positioned between the first polymer-based portion and the foldable substrate, ratio of elastic modulus between the first polymer-based portion and the first adhesive layer, etc.) can reduce (e.g., mitigate, avoid) instabilities of foldable apparatus during folding the foldable apparatus. For example, with reference to FIG. 12, a first instability 1207 is visible at the second major surface 1213 of the foldable apparatus 1201. As shown, the foldable apparatus can comprise five layers (e.g., regions) comprising three layers 1203a, 1203b, and 1203c with an elastic modulus greater than the other two layers 1205a and 1205b. In this example, an outer layer 1203c at the second major surface 1213 of the foldable apparatus 1201 exhibits wrinkling. Without wishing to be bound by theory, wrinkling can be caused by variations in the local stress experienced by the outer layer 1203c, where the bend-induced strain (e.g., in-plane strain relative to the second major surface 1213) exceeds a critical strain that the outer layer 1203c can withstand. Without wishing to be bound by theory, wrinkling can be the result of stress coupling (e.g., not decoupled) between adjacent layers and/or an adjacent pair of layers (e.g., 1203b and 1203c) with an elastic modulus greater than another layer 1205b positioned therebetween.

For example, with reference to FIG. 13, a second instability 1307 is exhibited by a first inner layer 1305a of a foldable apparatus 1301. As shown, the foldable apparatus can comprise five layers (e.g., regions) comprising three layers 1303a, 1303b, and 1303c with an elastic modulus greater than the other two layers 1305a and 1305b. In this example, the first inner layer 1305a exhibits thinning. As shown in FIG. 13, the solid lines deviate from the dashed lines, which represent the profile of the foldable apparatus 1301 without the second instability 1307. For example, a first thickness 1311 of the first inner layer 1305a is greater than a second thickness 1313 of the first inner layer 1305a. Further, a second inner layer 1305b can comprise a first thickness 1315 of the second inner layer 1305b that is greater than a second thickness 1317 of the second inner layer 1305b. Thinning of the first inner layer 1305a and/or second inner layer 1305b at a location comprising the second thickness 1313 or 1317, respectively, can cause optical distortions and/or contribute to failure of the foldable apparatus 1301 in subsequent folding events. Without wishing to be bound by theory, thinning of an inner layer 1305a and/or 1305b can be caused by variations in the local stress experienced by the corresponding inner layer, where the bend-induced exceeds a critical strain that the corresponding inner layer can withstand.

Throughout the disclosure, a neutral plane is a series of locations comprising substantially 0 strain when the foldable apparatus is folded in direction 111 (see FIG. 1). In aspects, where the foldable apparatus comprises a plurality of layers with each layer being substantially homogenous, a neutral plane of the foldable apparatus can comprise a plane extending substantially parallel to the first major surface 203 or 403 and/or second major surface 205 or 405 when the foldable apparatus is in an unfolded (e.g., flat) configuration. In further aspects, the foldable apparatus can comprise a plurality of neutral planes that are each substantially parallel to the first major surface 203 or 403 and/or second major surface 205 or 405 when the foldable apparatus is in an unfolded (e.g., flat) configuration. As used herein, a first neutral plane is a neutral plane where a first region closer to the first major surface relative to the neutral plane is positive (e.g., corresponding to tensile stress) and a second region closer to the second major surface relative to the neutral plane is negative (e.g., corresponding to compressive stress). In aspects, the first polymer-based portion 251, the second polymer-based portion 451 (if present), and/or the foldable substrate 201 or 407 can each comprise a first neutral plane.

As used herein, a second neutral plane is a neutral plane where a first region closer to the first major surface relative to the neutral plane is negative (e.g., corresponding to compressive stress) and a second region closer to the second major surface relative to the neutral plane is positive (e.g., corresponding to tensile stress). In aspects, the first adhesive layer 261 and/or the second adhesive layer 461 (if present) can comprise a second neutral plane.

In aspects, each first region of a plurality of first regions can comprise a first neutral plane and each second region of one or more second regions can comprise a second neutral plane. Throughout the disclosure, a second region comprises a maximum elastic modulus that is less than a minimum elastic modulus of an adjacent first region. As used herein, a second region is adjacent to another region if there is no other layer between the second region and the another region. Throughout the disclosure, a first region is an “adjacent” first region relative to a second region if there is no further first region between the first region and the second region. Further, the maximum elastic modulus of the second region is at least about 500 times less than the minimum elastic modulus of the adjacent first region. Consequently, a prospective region comprising a maximum elastic modulus that is more than a minimum elastic modulus of an adjacent first region is treated as part of the first region. A prospective region comprising a maximum elastic modulus that is less than a minimum elastic modulus of an adjacent first region by a multiple of less than 500 is treated as part of the first region. A prospective region comprising a maximum elastic modulus that is less than a minimum elastic modulus of an adjacent first region by a multiple of about 500 or more is treated as a second region, although a greater multiple may be specified in further aspects, for example, one or more of the values discussed above for the ratio of the elastic modulus of the first polymer-based portion 251 to the elastic modulus of the first adhesive layer 261.

Also, a prospective region can be classified relative to an adjacent second region. A prospective region comprising a minimum elastic modulus that is less than a maximum elastic modulus of an adjacent second region is treated as part of the adjacent second region. A prospective region comprising a minimum elastic modulus that is greater than a maximum elastic modulus of the adjacent second region by a multiple of less than 500 is treated as part of the adjacent second region. A prospective region comprising a minimum elastic modulus that is greater than a maximum elastic modulus of the adjacent second region by a multiple of about 500 or more is treated as a first region, although a greater multiple may be specified in further aspects, for example, one or more of the values discussed above for the ratio of the elastic modulus of the first polymer-based portion 251 to the elastic modulus of the first adhesive layer 261.

For example, with reference to FIG. 2, the first adhesive layer 261 can comprise a second region. A first adjacent region comprising the first polymer-based portion 251 is a first region since the ratio of the elastic modulus of the first polymer-based portion 251 (maximum elastic modulus) to the elastic modulus of the first adhesive layer 261 (minimum elastic modulus) is about 500 or more. Another adjacent region comprising the foldable substrate 201 is a first region since the ratio of the elastic modulus of the foldable substrate 201 (maximum elastic modulus) to the elastic modulus of the first adhesive layer 261 (minimum elastic modulus) is about 500 or more. In aspects, the foldable apparatus 101, 301, or 601 shown in FIGS. 2-3 and 6 can comprise two first neutral planes and one second neutral plane, where the first adhesive layer 261 comprises the second neutral plane, the foldable substrate 201 comprises a first neutral plane, and the first polymer-based portion comprises an another first neutral plane. In aspects, the foldable apparatus 401 or 501 shown in FIGS. 4-5 can comprise three first neutral planes and two second neutral planes, where the first adhesive layer 261 and the second adhesive layer 461 each comprise a second neutral plane, the foldable substrate 201 comprises a first neutral plane, and the first polymer-based portion 251 and the second polymer-based portion 451 each comprise a first neutral plane.

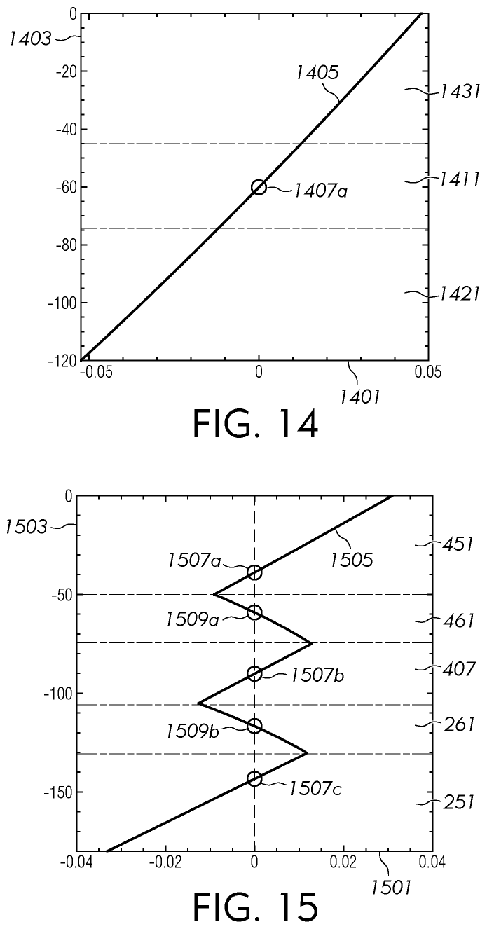

FIGS. 14-15 show plots of strain on the horizontal axis 1401 or 1501 as a function of distance in the direction 202 on the vertical axis 1403 or 1503 based on computer simulations. The simulations performed with the following assumptions: the foldable substrate comprises an elastic modulus of 71 GPa and a Poisson's ratio of 0.22; the adhesive layers comprise a Poisson's ratio of 0.49; the polymer-based portions comprise a Poisson's ratio of 0.49; all interfaces in the foldable apparatus are perfectly bonded with no delamination; a large deformation approach is applicable; and that all components were at 23° C. The curve 1505 shown in FIG. 15 corresponds to the strain experienced by a foldable apparatus resembling the foldable apparatus 501 shown in FIG. 5. It is expected that a curve of the strain experienced by a foldable apparatus resembling the foldable apparatus 401 shown in FIG. 4 would be very similar to the curve 1505 shown in FIG. 15 with the same number of neutral planes. The curve 1505 shows five neutral planes 1507a, 1507b, 1507c, 1509a, and 1509b. The curve 1505 has two second neutral planes 1509a and 1509b with a second neutral plane 1509a in the second adhesive layer 461 and another second neutral plane 1509b in the first adhesive layer. The curve 1505 has three first neutral plane 1507a, 1507b, and 1507c with a first neutral plane 1507a in the second polymer-based portion 451, another first neutral plane 1507b in the foldable substrate 407, and yet another first neutral plane 1507c in the first polymer-based portion 251.

FIG. 14 represents a comparative example. The curve 1405 shown in FIG. 14 corresponds to the strain experienced by a foldable apparatus like that shown in FIG. 4 but without the first adhesive layer between the first polymer-based portion and the foldable substrate and without the second adhesive layer between the second polymer-based portion and the foldable substrate, with region 1411 corresponding to the foldable substrate, region 1421 corresponding to the first polymer-based portion, and region 1431 corresponding to the second polymer-based portion. The curve 1405 has only one neutral plane 1407a, which is a first neutral plane. The ratio of the elastic moduli of adjacent regions (e.g., regions 1411 and 1421, regions 1411 and 1431) are less than 500, which means that all of the regions are of the same type (e.g., all first regions). Providing a foldable substrate where the number of neutral planes is equal to one less than the sum of the number of first regions and the number of second regions can enable decoupling of the first regions, which can result in a reduced bend force, reduced incidence of mechanical instabilities, reduced bend-induced stresses and/or strains, and/or reduced failure of the foldable apparatus.

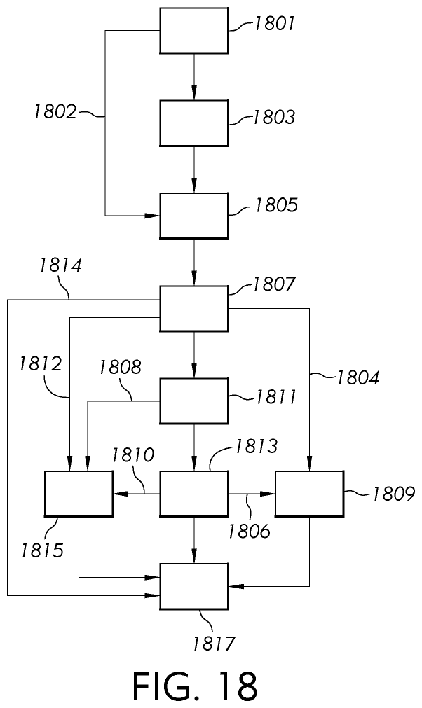

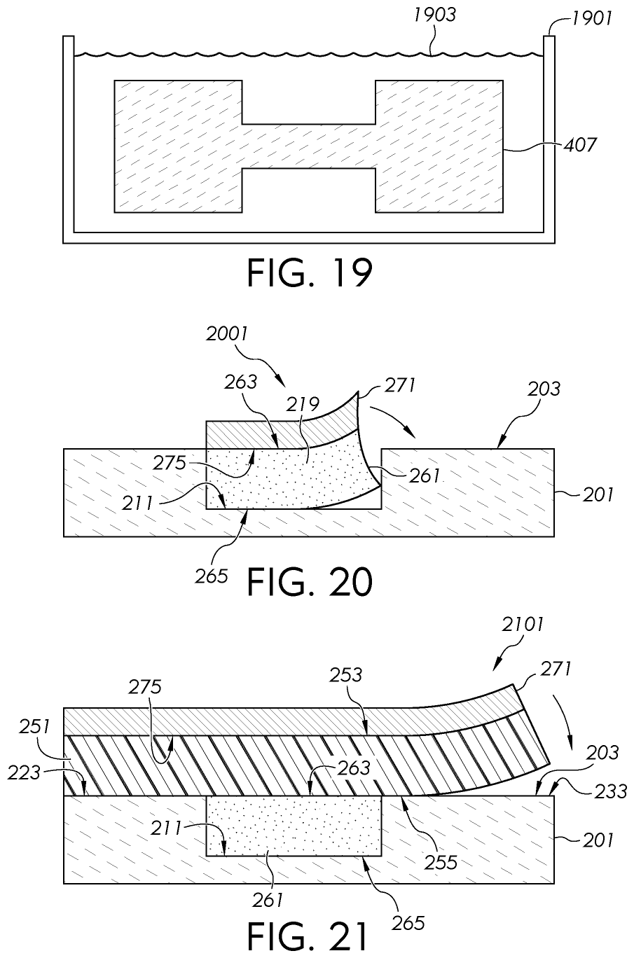

Aspects of methods of making the foldable apparatus 101, 301, 401, 501, and/or 601 in accordance with aspects of the disclosure will be discussed with reference to the flow chart in FIG. 18 and example method steps illustrated in FIGS. 19-26. With reference to the flow chart of FIG. 18, methods can start at step 1801. In aspects, step 1801 can comprise providing a substrate. In further aspects, the substrate can resemble the foldable substrate 201 or 407 of FIGS. 2-6 comprising the substrate thickness 227 or 411. In further aspects, the foldable substrate 201 or 407 can be provided by purchase or otherwise obtaining a substrate or by forming a substrate. In further aspects, the foldable substrate 201 or 407 can comprise a glass-based substrate and/or a ceramic-based substrate. In further aspects, glass-based substrates can be provided by forming them with a variety of ribbon forming processes, for example, slot draw, down-draw, fusion down-draw, up-draw, press roll, redraw, or float. In even further aspects, the foldable substrate can comprise one or more recesses. In even further aspects, the foldable substrate can be chemically strengthened and comprise a depth of compression (e.g., first depth of compression, second depth of compression), compressive stress (e.g., first maximum compressive stress, second maximum compressive stress), and/or depth of layer (e.g., first depth of layer, second depth of layer) within one or more of the corresponding ranges discussed above.

After step 1801, as shown in FIG. 19, methods can proceed to step 1803 comprising chemically strengthening the foldable substrate 407 to form one or more compressive stress regions. In aspects, as shown, chemically strengthening the foldable substrate 407 can comprise contacting at least a portion of a foldable substrate 407 comprising lithium cations and/or sodium cations with a salt solution 1903 contained in a salt bath 1901. Chemically strengthening a foldable substrate 407 (e.g., glass-based substrate, ceramic-based substrate) by ion exchange can occur when a first cation within a depth of a surface of a foldable substrate 407 is exchanged with a second cation within a molten salt or salt solution 1903 that has a larger radius than the first cation. For example, a lithium cation within the depth of the surface of the foldable substrate 407 can be exchanged with a sodium cation or potassium cation within a salt solution 1903. Consequently, the surface of the foldable substrate 407 is placed in compression and thereby chemically strengthened by the ion exchange process since the lithium cation has a smaller radius than the radius of the exchanged sodium cation or potassium cation within the salt solution 1903. Chemically strengthening the foldable substrate 407 can comprise contacting at least a portion of a foldable substrate 407 comprising lithium cations and/or sodium cations with a salt bath 1901 comprising salt solution 1903 comprising potassium nitrate, potassium phosphate, potassium chloride, potassium sulfate, sodium chloride, sodium sulfate, sodium nitrate, and/or sodium phosphate, whereby lithium cations and/or sodium cations diffuse from the foldable substrate 407 to the salt solution 1903 contained in the salt bath 1901. In aspects, the temperature of the salt solution 1903 can be about 300° C. or more, about 360° C. or more, about 400° C. or more, about 500° C. or less, about 460° C. or less, or about 420° C. or less. In aspects, the temperature of the salt solution 1903 can be in a range from about 300° C. to about 500° C., from about 360° C. to about 500° C., from about 400° C. to about 460° C., from about 400° C. to about 420° C., or any range or subrange therebetween. In aspects, the foldable substrate 407 can be in contact with the salt solution 1903 for about 5 minutes or more, about 30 minutes or more, about 1 hour or more, about 3 hours or more, about 48 hours or less, about 24 hours or less, or about 8 hours or less. In aspects, the foldable substrate 407 can be in contact with the salt solution 1903 for a time in a range from about 5 minutes to about 48 hours, from about 30 minutes to about 48 hours, from about 30 minutes to about 24 hours, from about 1 hour to about 24 hours, from about 3 hours to about 24 hours, from about 3 hours to about 8 hours, or any range or subrange therebetween. In aspects, the foldable substrate 407 can be in contact with the salt solution 1903 for a time in a range from about 5 minutes to about 8 hours, from about 30 minutes to about 8 hours, from about 1 hour to about 8 hours, or any range or subrange therebetween. In aspects, at the end of step 1803, the foldable substrate 407 can comprise one or more of the compressive stress regions that can comprise a depth of compression and/or maximum compressive stress within one or more of the corresponding ranges discussed above.

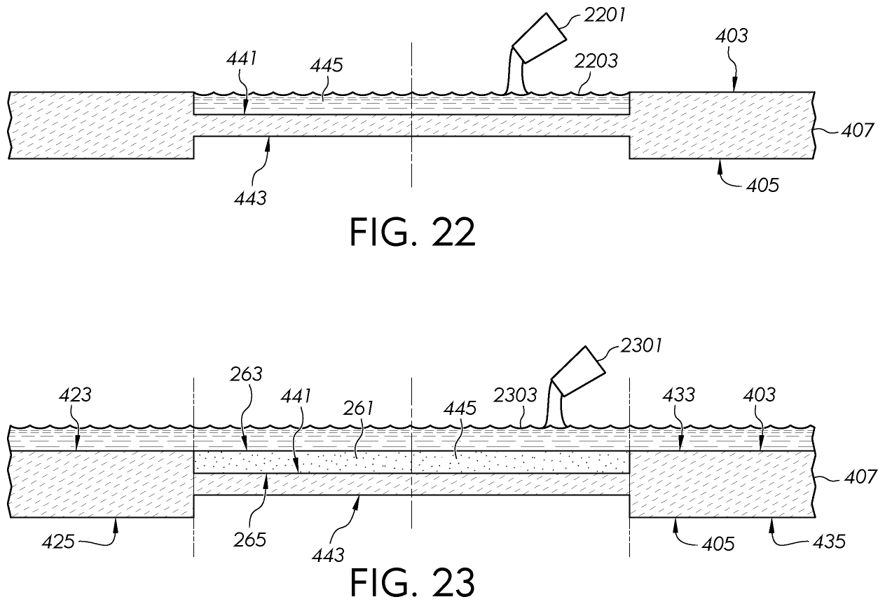

After step 1801 or step 1803, as shown in FIGS. 20 and 22, methods can proceed to step 1805 comprising disposing the first adhesive layer 261 in the first recess 219 or 445 of the foldable substrate 201 or 407. In aspects, as shown in FIG. 20, disposing the first adhesive layer 261 can comprise disposing one or more films 2001 on the first central surface area 211 and/or in the first recess 219. In further aspects, the one or more films 2001 can comprise a release liner 271 contacting one or more surfaces of the film 2001 that can be removed during the deposition process. For example, if a release liner contacts the second contact surface 265, that release liner is removed so that the second contact surface 265 can be disposed on and/or contact the first central surface area 211. For example, if a release liner contacts the first contact surface 263, that release liner can be removed before or after disposing the film 2001 (e.g., first adhesive layer 261) but before the end of step 1805. In aspects, a single film 2001 can be disposed on the first central surface area 211 (e.g., at least partially within the first recess 219, for example, if a thickness of the film 2001 is substantially equal to the thickness of the first adhesive layer 261. In aspects, multiple films 2001 can be disposed, for example, if a thickness of a film is less than a thickness of the first adhesive layer and/or if the first adhesive layer is to contact the first major surface 203. In further aspects, the films can be attached to one another before being disposed on the first central surface area 211 and/or the films can be deposited sequentially.

In aspects, as shown in FIG. 22, disposing the first adhesive layer 261 can comprise dispensing a first liquid 2203 at least partially into the first recess 445 and curing the first liquid 2203 to form the first adhesive layer 261. In further aspects, dispensing the first liquid 2203 can comprise dispensing the first liquid 2203 from a container 2201 (e.g., conduit, flexible tube, micropipette, or syringe). In further aspects, although not shown, dispensing the first liquid can comprise disposing the first liquid over the first contact surface area as well as the first major surface. In further aspects, curing the first liquid can comprise heating the first liquid 2203, irradiating the first liquid 2203 with ultraviolet (UV) radiation, and/or waiting a predetermined amount of time (e.g., from about 30 minutes to 24 hours, from about 1 hour to about 8 hours). In aspects, as shown in FIG. 23, the second contact surface 265 of the first adhesive layer 261 can face and/or contact the first central surface area 441.

After step 1805, as shown in FIGS. 21 and 23, methods can proceed to step 1807 comprising disposing a first polymer-based portion 251 on the first adhesive layer 261. In aspects, as shown in FIG. 21, disposing the first polymer-based portion 251 can comprise disposing one or more films 2101 on the first adhesive layer 261. In further aspects, the one or more films 2101 can comprise a release liner 271 contacting one or more surfaces of the film 2101 that can be removed during the deposition process. For example, if a release liner contacts the fourth contact surface 255, that release liner is removed so that the fourth contact surface 255 can be disposed on and/or contact the first contact surface 263 of the first adhesive layer 261. For example, if a release liner contacts the third contact surface 253, that release liner can be removed before or after disposing the film 2101 (e.g., first polymer-based portion 251) but before the end of step 1807. In aspects, a single film 2101 can be disposed on the first adhesive layer 261, for example, if a thickness of the film 2101 is substantially equal to the thickness of the first polymer-based portion 251. In aspects, multiple films 2101 can be disposed, for example, if a thickness of a film is less than a thickness of the first polymer-based portion and/or if the first adhesive layer is to be partially positioned in the first recess. In further aspects, the films can be attached to one another before being disposed on the first adhesive layer 261 and/or the films can be deposited sequentially.

In aspects, as shown in FIG. 23, disposing the first polymer-based portion 251 can comprise dispensing a second liquid 2303 on the first adhesive layer 261 and curing the second liquid 2303 to form the first polymer-based portion 251. In further aspects, dispensing the second liquid 2303 can comprise dispensing the second liquid 2303 from a second container 2301 (e.g., conduit, flexible tube, micropipette, or syringe). In further aspects, curing the second liquid 2303 can comprise heating the second liquid 2303, irradiating the second liquid 2303 with ultraviolet (UV) radiation, and/or waiting a predetermined amount of time (e.g., from about 30 minutes to 24 hours, from about 1 hour to about 8 hours).

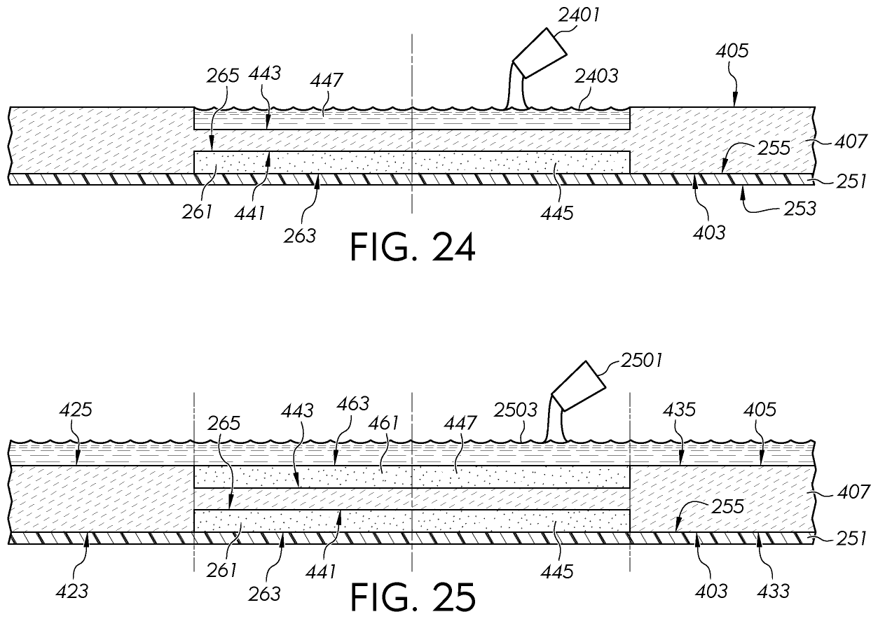

After step 1807, as shown in FIG. 24, methods can proceed to step 1811 comprising disposing the second adhesive layer 461 at least partially in the second recess 447 and/or on the second central surface area 443. In aspects, as shown in FIG. 24, step 1811 can comprise dispensing a third liquid 2403 from a third container 2401 (e.g., conduit, flexible tube, micropipette, or syringe) and then curing the third liquid 2403 (e.g., heating the third liquid 2403, irradiating the third liquid 2403, and/or waiting a predetermined amount of time) to form the second adhesive layer 461. In aspects, the third liquid 2403 can be the same as the first liquid 2203. In aspects, although not shown, disposing the second adhesive layer 461 can comprise disposing one or more films similar to or identical to that described above for step 1805. In aspects, the first adhesive layer 261 can comprise the same material as the second adhesive layer 461.

After step 1811, as shown in FIG. 25, methods can proceed to step 1813 comprising disposing the second polymer-based portion 451 on the second adhesive layer 461. In aspects, disposing the second polymer-based portion 451 can comprise dispensing a fourth liquid 2503 from a fourth container 2501 (e.g., conduit, flexible tube, micropipette, or syringe) on the second adhesive layer 461 and curing the fourth liquid 2503 (e.g., heating the fourth liquid 2503, irradiating the fourth liquid 2503, and/or waiting a predetermined amount of time) to form the second polymer-based portion 451. For example, at the end of step 1813, the foldable apparatus can be identical to the foldable apparatus 501 shown in FIG. 5 other than the absence of the display device 307. In aspects, although not shown, disposing the second polymer-based portion can comprise disposing one or more films on the second adhesive layer similar to or identical to that described above for step 1807. In aspects, the first polymer-based portion 251 can comprise the same material as the second polymer-based portion 451. In aspects, the second polymer-based portion 451 can comprise a pencil hardness of about 5H or more and/or within one or more of the ranges discussed above for the pencil hardness of the coating 471.

After step 1807, step 1811, or step 1813, as shown in FIG. 25, methods can proceed to step 1815 comprising disposing the coating 471 on the foldable substrate 407. In aspects, as shown, the coating 471 can be disposed on the second adhesive layer 461. In aspects, as shown, disposing the coating can comprise dispensing a fourth liquid 2503 from a container 2501 (e.g., conduit, flexible tube, micropipette, or syringe) on the second adhesive layer 461 and curing the fourth liquid 2503 (e.g., heating the fourth liquid 2503, irradiating the fourth liquid 2503, and/or waiting a predetermined amount of time) to form the coating 471. It is to be understood that the fourth liquid 2503 can be used to form the second polymer-based portion 451 (in step 1813) and/or the coating 471 (in the present step 1815). In aspects, the coating 471 can be at least partially positioned in the second recess 447 as shown in FIG. 6. In aspects, although not shown, the fourth liquid can be disposed over the second polymer-based portion and curing the fourth liquid can form the coating 471 disposed on the second polymer-based portion 451 as shown in FIG. 4. In aspects, although not shown, the fourth liquid can occupy the second recess in addition to the region shown in FIG. 25 such that curing the fourth liquid produces the coating 471 shown in FIG. 6. In aspects, the coating 471 can comprise a pencil hardness of about 5H or more and/or within one or more of the ranges discussed above for the pencil hardness of the coating 471.

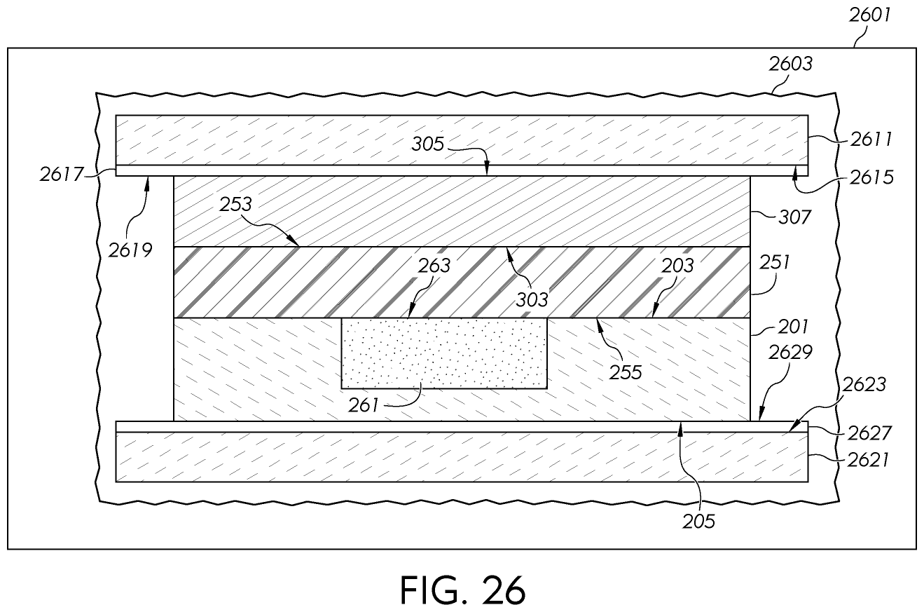

After step 1807 or step 1813, as shown in FIG. 26, methods can proceed to step 1809 comprising a thermal lamination process. In aspects, step 1809 can comprise disposing one or more elements (e.g., display device 307) over the third contact surface 253 of the first polymer-based portion 251. In further aspects, as shown, step 1809 can comprise applying a first release liner 2617 over the display device 307. As shown, the first release liner 2617 can comprise a first surface area 2619 facing the third contact surface 253, which can further contact the fourth major surface 305 of the display device 307. In even further aspects, a first support 2611 can be disposed over the first release liner 2617, for example, with a third surface 2615 of the first support 2611 facing and/or contacting the first release liner 2617. In further aspects, as shown in FIG. 26, step 1809 can comprise applying a second release liner 2627 over the second major surface 205 of the foldable substrate 201. In even further aspects, a first surface area 2629 of the second release liner 2627 can face and/or contact the second major surface 205 of the foldable substrate 201. In even further aspects, a second support 2621 can be disposed over the second release liner 2627, for example, with a third surface 2623 of the second support 2621 facing and/or contacting the second release liner 2627. In further aspects, as shown in FIG. 26, methods can comprise placing the assembly in a vacuum container 2603. In even further aspects, the vacuum container can provide an airtight closure and can withstand the conditions of the thermal lamination process. Exemplary aspects of vacuum containers include the OBSJ/ABSJ vacuum bags available from Simtech. In further aspects, the first release liner 2617 and/or the second release liner 2627 can comprise any of the material discussed above for release liner 271, for example a fluorine-containing polymer. In further aspects, the first support 2611 and/or the second support 2621 can comprise an elastic modulus of about 3 GPa or more and/or can comprise a glass-based material and/or a ceramic-based material. Providing one or more release liners can reduce (e.g., prevent) adhesion of the film to undesired materials during methods and can reduce damage to the laminate during processing. Providing one or more supports can decrease deformation (e.g., warp) of the substrate and/or film during processing. Providing a vacuum container can protect the substrate, film, and/or laminate from contamination during processing.

In aspects, step 1809 can further comprise heating the foldable substrate at a first temperature for a first period of time. In further aspects, as shown in FIG. 26, heating the assembly can comprise placing the film and the substrate in an oven 2601. In further aspects, the first temperature can be about 40° C. or more, about 50° C. or more, about 60° C. or more, about 100° C. or less, about 90° C. or less, about 80° C. or less, or about 70° C. or less. In further aspects, the first temperature can be in a range from about 40° C. to about 100° C., from about 50° C. to about 90° C., from about 50° C. to about 80° C., from about 60° C. to about 70° C., or any range or subrange therebetween. In further aspects, the first period of time can be about 10 minutes or more, about 15 minutes or more, about 20 minutes or more, about 25 minutes or more, about 8 hours or less, about 4 hours or less, about 2 hours or less, about 1 hour or less, about 45 minute or less, or about 35 minutes or less. In further aspects, the first period of time can be in a range from about 10 minutes to about 8 hours, from about 15 minutes to about 4 hours, from about 15 minutes to about 2 hours, from about 20 minutes to about 1 hour, from about 25 minutes to about 45 minutes, from about 25 minutes to about 35 minutes, or any range or subrange therebetween. In even further aspects, step 1809 can comprise heating the film and the substrate from ambient temperature (e.g., about 25° C.) to the first temperature at a first rate. In even further aspects, the first rate can be about 0.1° C. per minute (° C./min) or more, about 0.5° C./min or more, about 1° C./min or more, about 10° C./min or less, about 5° C./min or less, or about 3° C./min or less. In even further aspects, the first rate can be in a range from about 0.1° C./min to about 10° C./min, from about 0.5° C./min to about 5° C./min, from about 1° C./min to about 3° C./min, or any range or subrange therebetween.

In aspects, step 1809 can further comprise heating the foldable substrate at a second temperature for the second period of time at the gauge pressure, for example, after heating the foldable substrate at a first temperature for a first period of time. As used herein, gauge pressure refers to pressure measured relative to atmospheric pressure (e.g., about 101.325 kPa). In further aspects, the second temperature can be about 150° C. or more, about 170° C. or more, about 190° C. or more, about 250° C. or less, about 230° C. or less, or about 210° C. or less. In further aspects, the second temperature can be in a range from about 150° C. to about 250° C., from about 170° C. to about 230° C., from about 190° C. to about 210° C., or any range or subrange therebetween. In further aspects, the second period of time can be about 30 minutes or more, about 35 minutes or more, about 40 minutes or more, about 2 hours or less, about 50 minutes or less, or about 45 minutes or less. In further aspects, the second period of time can be in a range from about 30 minutes to about 2 hours, from about 35 minutes to about 50 minutes, from about 40 minutes to about 45 minutes, or any range or subrange therebetween. In further aspects, the gauge pressure can be positive. In further aspects, the gauge pressure can be about 1.0 MegaPascals (MPa) or more, about 1.1 MPa or more, about 1.2 MPa or more, about 1.5 MPa or less, about 1.4 MPa or less, or about 1.3 MPa or less. In further aspects, the gauge pressure can be in a range from about 1.0 MPa to about 1.5 MPa, from about 1.1 MPa to about 1.4 MPa, from about 1.2 MPa to about 1.3 MPa, or any range or subrange therebetween. In further aspects, the second temperature can be greater than the first temperature. In even further aspects, step 1809 can comprise heating the film and the substrate from the first temperature to the second temperature at a second rate. In still further aspects, the second rate can be about 0.1° C. per minute (° C./min) or more, about 0.5° C./min or more, about 1° C./min or more, about 10° C./min or less, about 5° C./min or less, or about 3° C./min or less. In even further aspects, the second rate can be in a range from about 0.1° C./min to about 10° C./min, from about 0.5° C./min to about 5° C./min, from about 1° C./min to about 3° C./min, or any range or subrange therebetween. In further aspects, step 1809 can comprise increasing a pressure at a third rate to reach the gauge pressure. In even further aspects, the third rate can be about 3 kiloPascals per minute (kPa/min) or more, about 7 kPa/min or more, about 10 kPa/min or more, about 15 kPa/min or more, about 50 kPa/min or less, about 35 kPa/min or less, about 30 kPa/min or less, about 25 kPa/min or less, or about 20 kPa/min or less. In even further aspects, the third rate can be in a range from about 3 kPa/min to about 50 kPa/min, from about 7 kPa/min to about 35 kPa/min, from about 10 kPa/min to about 30 kPa/min, from about 15 kPa/min to about 25 kPa/min, from about 15 kPa/min to about 20 kPa/min, or any range or subrange therebetween.

In further aspects, step 1809 can comprise cooling the foldable substrate from the second temperature to ambient temperature (e.g., about 25° C.) or another predetermined temperature at a fourth rate after heating the foldable substrate at the first temperature for the first period of time and/or the second temperature for the second period of time at a gauge pressure. In even further aspects, the fourth rate can be about 0.5° C./min or more, about 1° C./min or more, about 2° C./min or more, about 4° C./min or more, about 20° C./min or less, about 10° C./min or less, about 8° C./min or less, or about 6° C./min or less. In even further aspects, the fourth rate can be in a range from about 0.5° C./min to about 20° C./min, from about 1° C./min to about 10° C./min, from about 2° C./min to about 8° C./min, from about 4° C./min to about 6° C./min, or any range or subrange therebetween. In further aspects, step 1809 can further comprise decreasing a pressure from the gauge pressure to ambient pressure (i.e., 0 Pascals gauge pressure) or another predetermined pressure at a fifth rate. In even further aspects, the fifth rate can be about 10 kPa/min or more, about 35 kPa or more, about 50 kPa/min or more, about 103 kPa/min or less, about 80 kPa/min or less, or about 60 kPa/min or less. In even further aspects, the fifth rate can be in a range from about 10 kPa/min to about 103 kPa/min, from about 35 kPa/min to about 80 kPa/min, from about 50 kPa/min to about 60 kPa/min, or any range or subrange therebetween. In further aspects, step 1809 can comprise removing the formed foldable apparatus from the vacuum container, support layer(s), and/or release liner(s) if present.

In aspects, after step 1807, step 1809, step 1813, or step 1815 methods can proceed to step 1817. In aspects, step 1817 can comprise further assembling the foldable apparatus, for example, including the foldable apparatus in the consumer electronic device shown in FIGS. 10-11. In aspects methods of the disclosure can be complete at step 1817.

In aspects, as discussed above with reference to the flow chart in FIG. 18, methods can start at step 1801 and then proceed sequentially through steps 1801, 1803, 1805, 1805, 1807, 1811, 1813, and 1817. In aspects, arrow 1802 can be followed from step 1801 to step 1805, for example, if the foldable substrate is already chemically strengthened at the end of step 1801 or if the foldable substrate is not to be chemically strengthened during the method. In aspects, arrow 1804 can be followed from step 1807 to step 1809, for example, if the first adhesive layer 261 and/or the first polymer-based portion 251 was disposed as a film to be thermally laminated in step 1809 and the foldable apparatus comprises a single recess (e.g., first recess 219) like foldable apparatus 101 or 301 shown in FIGS. 2-3. In aspects, arrow 1806 can be followed from step 1813 to step 1809, for example, if the first adhesive layer 261, the first polymer-based portion 251, the second adhesive layer 461, and/or the second polymer-based portion 451 was disposed as a film to be thermally laminated in step 1809 and the foldable apparatus comprises both a first recess 445 and a second recess 447. In aspects, arrow 1808 can be followed from step 1811 to step 1815, for example, if the coating 471 is to be disposed on the second adhesive layer 461. In aspects, arrow 1810 can be followed from step 1813 to step 1815, for example, if the coating 471 is to be disposed on the second polymer-based portion 451 to form a foldable apparatus resembling the foldable apparatus 501 shown in FIG. 5. In aspects, arrow 1812 can be followed from step 1807 to step 1815, for example, if the coating 471 is to be disposed on the second major surface 205 or 405 and/or in the second recess 447 to form the foldable apparatus 101 or 601 shown in FIGS. 2 and 6. In aspects, arrow 1814 can be followed from step 1807 to step 1817, for example, if the method is complete at the end of step 1807 (e.g., see FIGS. 2-3). Any of the above options may be combined to make a laminate in accordance with aspects of the disclosure.

### Examples

Various aspects will be further clarified by the following examples. Examples A-B and AA-GG all comprise foldable apparatus comprising a foldable substrate comprising a glass-based substrate (Composition 1 having a nominal composition in mol % of: 63.6 SiO₂; 15.7 Al₂O₃; 10.8 Na₂O; 6.2 Li₂O; 1.16 ZnO; 0.04 SnO₂; and 2.5 P₂O₅) with a substrate thickness 411 of 100 μm, a central thickness of 30 μm 427, where a width 449 of the central portion 481 is 20 mm, the first central surface area 441 is recessed from the first major surface 403 by 35 μm, and the second central surface area 443 is recessed from the second major surface 405 by 35 μm. Example AA comprises the foldable substrate alone without any material disposed thereon. Examples BB-EE comprise a single material disposed on the first major surface 403 and the first central surface area 441 and another single material disposed on the second major surface 405 and the second central surface area 443, where the thicknesses and elastic moduli of these materials are presented in Table 1. As shown, the thickness of the materials were 45 μm, which filled the corresponding recess and extended beyond the recess with a thickness of 10 μm over the first portion and the second portion.

TABLE 1
Thickness and Elastic Modulus for Examples AA-EE.

| Example | AA | BB | CC | DD | EE |
|---|---|---|---|---|---|
| Thickness of first | 0 | 45 | 45 | 45 | 45 |
| material on first central | | | | | |
| surface area (μm) | | | | | |
| Thickness of first | 0 | 10 | 10 | 10 | 10 |
| material on first major | | | | | |
| surface (μm) | | | | | |
| Elastic modulus of | — | 2.4 | 1,500 | 3,000 | 3,000 |
| first material (MPa) | | | | | |
| Thickness of second | 0 | 45 | 45 | 45 | 45 |
| material on second | | | | | |
| central surface area | | | | | |
| (μm) | | | | | |
| Thickness of second | 0 | 10 | 10 | 10 | 10 |
| material on second | | | | | |
| major surface (μm) | | | | | |
| Elastic modulus of | — | 2.4 | 1,500 | 2.4 | 3,000 |
| second material (MPa) | | | | | |

Example A resembles the foldable apparatus shown in FIG. 4 but with the second polymer-based portion occupying the space shown for the second polymer-based portion 451 and the coating 471. Example A comprises a first adhesive layer positioned at least partially within the first recess and positioned between the first central surface area and the first polymer-based portion, and Example A comprises a second adhesive layer positioned at least partially within the second recess and positioned between the second central surface area and the second polymer-based portion. The thickness and elastic modulus of the adhesive layers and polymer-based portions are shown in Table 2. As shown, the adhesive layer (i.e., the first adhesive layer and the second adhesive layers) comprises an elastic modulus of 0.12 MPa (corresponding to CEF35 OCA available from 3M) and a thickness of 25 μm positioned entirely in the corresponding recess and contacting the corresponding central surface area. The polymer-based portion (i.e., the first polymer-based portion and the second polymer-based portion) comprises an elastic modulus of 3,300 MPa and a maximum thickness of 25 μm consisting of 10 μm in the corresponding recess and 15 μm disposed thereon and on the corresponding major surface.

TABLE 2
Thickness and Elastic Moduli for Example A.

| | | First | | Second |
|---|---|---|---|---|
| | First | Polymer- | Second | Polymer- |
| | Adhesive | based | Adhesive | based |
| | Layer | Portion | Layer | Portion |
| Thickness on the first | 25 | 25 | — | — |
| central surface area (μm) | | | | |
| Thickness on the first | 0 | 15 | — | — |
| major surface (μm) | | | | |
| Elastic modulus (MPa) | 0.12 | 3,300 | 0.12 | 3,300 |
| Thickness on the second | — | — | 25 | 25 |
| central surface area (μm) | | | | |
| Thickness on the second | — | — | 0 | 15 |
| major surface (μm) | | | | |

Unless otherwise indicated, the properties presented herein for Examples A-B and AA-GG were calculated based on simulations performed with the following assumptions: the foldable substrate comprises an elastic modulus of 71 GPa and a Poisson's ratio of 0.22; the adhesive layers comprise a Poisson's ratio of 0.49; the polymer-based portions comprise a Poisson's ratio of 0.49; the probe (for quasi-static indentation) was modeled as a rigid body with no tip deformation that did not penetrate the foldable apparatus; all interfaces in the foldable apparatus are perfectly bonded with no delamination; a large deformation approach is applicable; and that all components were at 23° C.

Table 3 presents the minimum bend force to achieve a parallel plate distance of 3 mm for Examples A and AA-EE. Example AA comprises the lowest bend force, and Example AA does not comprise any material disposed on the foldable substrate. Example BB comprises a bend force that is about 10% more than that of Example AA, and Example BB comprises a low elastic modulus disposed on each major surface and central surface area. Examples CC-DD comprise a bend force from 14.2 N/mm to 14.4 N/mm, which is about 160% or more greater than that of Example AA. Examples CC and DD have a material comprising an elastic modulus of more than 1 GPa (e.g., 1.5 GPa, 3 GPa) disposed on one or more central surface area. Example EE comprises a bend force of 22.6 N/mm, which is more than 300% greater than Example AA and about 60% greater than Example CC. Example EE comprises a material comprising an elastic modulus of 3.3 GPa disposed on each major surface and central surface area. Consequently, it would be expected that providing one material with an elastic modulus of about 1 GPa or more on a central surface area (e.g., first central surface area) will increase the bend force, that the bend force will be further increased by providing another material with an elastic modulus of 1 GPa on the other central surface area (e.g., second central surface area), and that the bend force will be further increased by increasing the elastic modulus of the material(s).

As discussed above, Example A comprises a first polymer-based portion and a second polymer-based portion each comprising an elastic modulus of 3.3 GPa disposed on the first central surface area and the second central surface area, respectively. Consequently, it would be expected that the bend force would be similar to that of Example EE. However, Example A comprises a bend force of 9.4 N/mm, which is about 30% less than that of Examples CC-DD and about 60% less than that of Example EE. The difference between Example EE and Example A is that Example A comprises an adhesive layer positioned between the corresponding central surface area and the corresponding polymer-based portion. Further, even though the adhesive layers of Example A do not completely fill the recesses, Example A is able to provide a reduced bend force compared to Examples CC-DD. It is expected that increasing the thickness of one or both adhesive layers would achieve similar results to that of Example A.

TABLE 3
Bend Force for Examples A and AA-EE

| | Bend Force |
|---|---|
| Example | (N/mm width) |
| AA | 5.4 |
| BB | 5.9 |
| CC | 14.2 |
| DD | 14.4 |
| EE | 22.6 |
| A | 9.4 |

As discussed above, FIGS. 14-15 present strain on the horizontal axis 1401 or 1501 as a function of distance in the direction. Curve 1405 corresponds to Examples BB and DD since the curves for Examples BB and DD substantially superimpose on one another. Consequently, Examples BB and DD only comprise one neutral axis. When there is only one material disposed on each central surface area, where each material disposed on the corresponding central surface comprises the same elastic modulus, there will be only one neutral axis. In contrast, curve 1505 corresponds to Example B. Example B is the same as Example A, but the thickness of the polymer-based portions is 50 μm (instead of 25 μm) over the corresponding central surface area and 40 μm (instead of 15 μm) on the corresponding major surface. As shown, curve 1505 comprises 5 neutral axes with a first neutral axis within the foldable substrate, a second neutral axis within each adhesive layer, and a first neutral axis within the corresponding polymer-based portion. Comparing Examples BB and DD to Example B, providing an adhesive layer between the corresponding polymer-based portion and the foldable substrate (e.g., corresponding central surface area) enables the additional neutral axes, which can lead to decoupling of the foldable substrate from the polymer-based portion, a reduced bend force, reduced incidence of mechanical instabilities, reduced bend-induced stresses and/or strains, and/or reduced failure of the foldable apparatus.

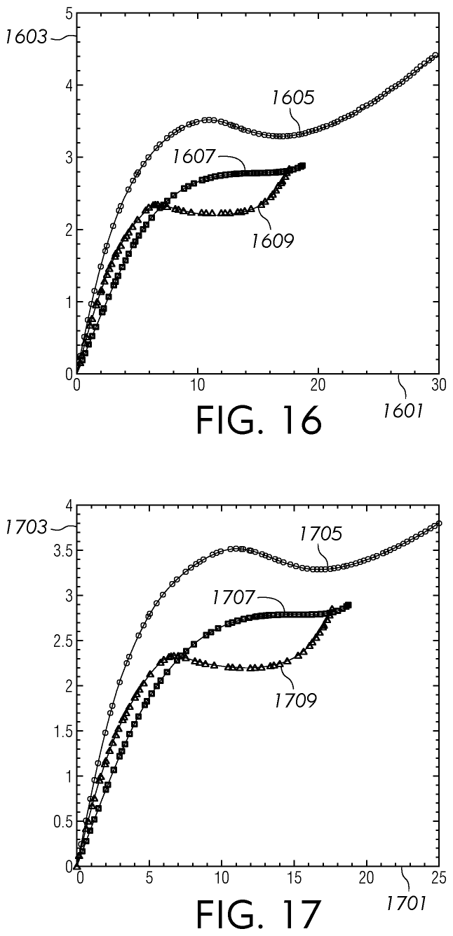

FIGS. 16-17 present results of quasit-static indentation tests for Examples B and FF-GG. As indicated above, the results in FIGS. 16-17 are from simulations, but these properties can be measured in accordance with ASTM D6264M-17 using the specified probe size (i.e., tip diameter of 0.5 mm) in combination with digital image correlation methods. The probe is applied to an outer surface that the second central surface area faces. FIG. 16 presents the stress (in GPa) at the second central surface area on the vertical axis 1603 as a function of force (in N) applied by the probe on the horizontal axis 1601. Lower stress is associated with better impact resistance. Curve 1605 (Example GG) has the highest stress shown. Curve 1607 (Example FF) has less stress than curve 1605. This decreased stress of Example FF compared to Example GG is likely the result of the additional 50 μm PET layer. Curve 1609 (Example B) is similar to curve 1607 for forces up to about 8 N with only slightly higher stress. From 6 N to about 18 N, curve 1609 corresponds to lower stress than curve 1607 or curve 1605. Without wishing to be bound by theory, it is believed that the neutral planes (see FIG. 15) introduced by providing the adhesive layer between the polymer-based portion and the foldable substrate enable decoupling of the stiffer layers (i.e., foldable substrate, polymer-based portions), which reduces the stress on the foldable substrate (e.g., at the second central surface area) for forces from about 8 N to about 18 N.

FIG. 17 presents the stress (in GPa) at the first central surface area on the vertical axis 1703 as a function of force (in N) applied by the probe on the horizontal axis 1701. Curve 1705 (Example GG) has the highest stress shown. Curve 1707 (Example FF) has less stress than curve 1705. This decreased stress of Example FF compared to Example GG is likely the result of the additional 50 μm PET layer. Curve 1709 (Example B) is similar to curve 1707 for forces up to about 8 N with only slightly higher stress. From 6 N to about 18 N, curve 1709 corresponds to lower stress than curve 1707 or curve 1705. Without wishing to be bound by theory, it is believed that the neutral planes (see FIG. 15) introduced by providing the adhesive layer between the polymer-based portion and the foldable substrate enable decoupling of the stiffer layers (i.e., foldable substrate, polymer-based portions), which reduces the stress on the foldable substrate (e.g., at the first central surface area) for forces from about 8 N to about 18 N.

A foldable apparatus according to the aspects of the disclosure can provide several technical benefits. For example, the foldable substrate can provide a small parallel plate distance while simultaneously providing good impact and puncture resistance. The foldable apparatus can comprise glass-based and/or ceramic-based materials comprising one or more compressive stress regions, which can further provide increased impact resistance and/or puncture resistance while simultaneously facilitating good bending performance.

Providing an adhesive layer between a polymer-based portion and a central surface area of the foldable substrate can provide a neutral plane within the first adhesive portion. Providing a low elastic modulus (e.g., about 0.4 MPa or less), a thickness of about 5 μm or more, and/or a low flexural rigidity (e.g., about 10⁻⁷ Pa m³ or less) can enable a neutral plane within the adhesive layer and/or reduce bend-induced stresses in adjacent first portions, which can reduce the incidence of bend-induced mechanical instabilities.

Providing an adhesive layer and/or a polymer-based portion with a glass transition temperature outside of an operating range (e.g., from about 0° C. to about 40° C., from about −20° C. to about 60° C.) of a foldable apparatus can enable the foldable apparatus to have consistent properties across the operating range. Providing an adhesive layer comprising a much lower (e.g., from about 500 times to about 500,000 times, from about 10,000 times to about 100,000 times) elastic modulus and/or flexural rigidity than a polymer-based portion can reduce bend-induced stresses on the polymer-based portion or the foldable substrate. Reducing bend-induced stresses can reduce (e.g., decreases, eliminate) bend-induced mechanical instabilities of the foldable apparatus. Also, reducing bend-induced stresses can reduce fatigue of the foldable apparatus while increasing the reliability and/or durability of the foldable apparatus. Without wishing to be bound by theory, it is believed that the neutral planes introduced by providing the adhesive layer between the polymer-based portion and the foldable substrate enable decoupling of the stiffer layers (i.e., foldable substrate, polymer-based portions). Providing more than one neutral plane (e.g., second neutral plane) can reduce (e.g., mitigate, avoid) instabilities of foldable apparatus during folding the foldable apparatus. Providing a foldable substrate where the number of neutral planes is equal to one less than the sum of the number of first regions (e.g., polymer-based portions and foldable substrate) and the number of second region (e.g., adhesive layers) can enable decoupling of the first regions, which can result in a reduced bend force, reduced incidence of mechanical instabilities, reduced bend-induced stresses and/or strains, and/or reduced failure of the foldable apparatus. Providing a foldable apparatus with an apparatus bend force near (e.g., within a factor of 2, from about 0.5 times to about 1 times) a total bend force from bending each first portion individually can enable low user-applied forces to fold the foldable apparatus. Also, this can reflect a decreased coupling of bend-induced stresses between adjacent pairs of first portions.

Providing a low (e.g., 4% or less) strain of the first polymer-based portion when the foldable apparatus achieves a parallel plate distance of 3 mm can reduce requirements for the first polymer-based portion, which can reduce failure of the foldable apparatus, and/or enable the use of a wider range of materials for the polymer-based portion since the strain requirements have been eased. Providing a low (e.g., 900 MPa or less) bending stress on the central portion of the foldable apparatus when the foldable apparatus achieves a parallel plate distance of 3 mm can decrease a bend force and/or reduce failure of the foldable apparatus. Providing one or more indices of refraction that substantially matches an index of refraction of the foldable substrate first can reduce (e.g., mitigate, avoid) optical distortions that may otherwise occur with a mismatched index of refraction.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

1. A foldable apparatus comprising:
a foldable substrate comprising
a substrate thickness defined between a first major surface and a second major surface opposite the first major surface, the substrate thickness is in a range from about 100 micrometers to about 2 millimeters;
a first portion comprising the substrate thickness;
a second portion comprising the substrate thickness; and
a central portion positioned between the first portion and the second portion, the central portion comprising a central thickness defined between a first central surface area and a second central surface area opposite the first central surface area, and the central thickness is less than the substrate thickness, the first central surface area is recessed from the first major surface by a first distance and defines a first recess;
a first adhesive layer disposed in the first recess, the first adhesive layer comprising a first adhesive thickness of about 5 micrometers or more, the first adhesive layer comprising an elastic modulus of about 0.4 MegaPascals or less; and
a first polymer-based portion disposed on the first adhesive layer such that the first adhesive layer is positioned between the first central surface area and the first polymer-based portion.

2. The foldable apparatus of claim 1, wherein the first adhesive thickness is defined between a first contact surface of the first adhesive layer facing the first polymer-based portion and a second contact surface of the first adhesive layer facing the first central surface area, the first contact surface and the second contact surface face opposite directions, the first polymer-based portion comprising a first polymer thickness defined between a third contact surface and a fourth contact surface facing the first adhesive layer, the third contact surface of the first polymer-based portion and the fourth contact surface of the first polymer-based portion facing opposite directions, and the first contact surface contacts the fourth contact surface.

3. The foldable apparatus of claim 2, wherein an absolute value of a strain of the first polymer-based portion at the third contact surface is about 4% or less when the foldable apparatus achieves a parallel plate distance of 3 millimeters.

4. The foldable apparatus of claim 2, wherein an absolute value of a bending stress of the central portion at the first central surface area is about 900 MegaPascals or less when the foldable apparatus achieves a parallel plate distance of 3 millimeters.

5. The foldable apparatus of claim 2, wherein a bend force to achieve a parallel plate distance of 3 millimeters is about 0.01 Newtons per millimeter width of the foldable apparatus (N/mm) or less.

6. The foldable apparatus of claim 2, wherein the foldable apparatus is configured to achieve a parallel plate distance in a range from about 1 millimeter to about 10 millimeters.

7. The foldable apparatus of claim 2, wherein the fourth contact surface of the first polymer-based portion contacts a first surface area of the first portion, the first surface area opposite a second surface area of the first portion with the substrate thickness therebetween, the fourth contact surface of the first polymer-based portion contacts a third surface area of the second portion, the third surface area opposite a fourth surface area of the second portion with the substrate thickness therebetween.

8. The foldable apparatus of claim 1, wherein the first adhesive thickness is less than the first distance.

9. The foldable apparatus of claim 1, wherein the first adhesive thickness is substantially equal to the first distance.

10. The foldable apparatus of claim 1, wherein the first adhesive layer is positioned between the first polymer-based portion and the first portion, and the first adhesive layer is positioned between the first polymer-based portion and the second portion.

11. The foldable apparatus of claim 1, inclusive, wherein the first adhesive thickness is greater than the first distance by about 5 micrometers or more.

12. The foldable apparatus of claim 1, wherein a ratio of an elastic modulus of the first polymer-based portion to the elastic modulus of the first adhesive layer is about 500 times or more.

13. The foldable apparatus of claim 1, wherein the first polymer-based portion comprises an elastic modulus of about 1 GigaPascal or more.

14. The foldable apparatus of claim 1, wherein the first polymer-based portion comprises a strain at yield in a range from about 3% to about 10%.

15. The foldable apparatus of claim 1, wherein the second central surface area is recessed from the second major surface by a second distance and defines a second recess, the foldable apparatus further comprising:
a second adhesive layer positioned in the second recess, the second adhesive layer comprising a second adhesive thickness; and
a second polymer-based portion disposed on the second adhesive layer such that the second adhesive layer is positioned between the second polymer-based portion and the second central surface area.

16. The foldable apparatus of claim 15, wherein the second polymer-based portion comprises a pencil hardness of about 5H or more, and the second polymer-based portion comprises an elastic modulus of about 1 GigaPascal or more.

17. The foldable apparatus of claim 1, wherein the foldable substrate comprises a first neutral plane extending through the first portion, the second portion, and the central portion, the first adhesive layer comprises a second neutral plane, and the polymer-based portion comprises an another first neutral plane.

18. The foldable apparatus of claim 1, wherein an apparatus bend force is in a range from about 0.5 times to about 1 times a total bend force comprising a force to bend each component of the foldable apparatus individually.

19. The foldable apparatus of claim 1, wherein a width of central portion defined between the first portion and the second portion is in a range from about 10 millimeters to about 30 millimeters.

20. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed on the display,
wherein at least one of a portion of the housing or the cover substrate comprises the foldable apparatus of claim 1.
